(19) United States
(12) Patent Application Publication
(10) Pub. No.: US 2023/0408914 A1
(43) Pub. Date: Dec. 21, 2023

(54) RESIN, RESIN COMPOSITION, AND DISPLAY DEVICE USING THE SAME

(71) Applicant: DUK SAN NEOLUX CO., LTD., Cheonan-si, Chungcheongnam-do (KR)

(72) Inventors: Changmin LEE, Cheonan-si, Chungcheongnam-do (KR); Yun Jong KO, Cheonan-si, Chungcheongnam-do (KR); Jun BAE, Cheonan-si, Chungcheongnam-do (KR); Jun Ki KIM, Cheonan-si, Chungcheongnam-do (KR); Jaehyun LIM, Cheonan-si, Chungcheongnam-do (KR); Seo Jeong JEON, Cheonan-si, Chungcheongnam-do (KR); Soung Yun MUN, Cheonan-si, Chungcheongnam-do (KR)

(73) Assignee: DUK SAN NEOLUX CO., LTD., Cheonan-si, Chungcheongnam-do (KR)

(21) Appl. No.: 18/247,703

(22) PCT Filed: Oct. 4, 2021
(86) PCT No.: PCT/KR2021/013547

§ 371 Date: Apr. 3, 2023

(30) Foreign Application Priority Data
Oct. 6, 2020 (KR) 10-2020-0128620

(51) Int. Cl. G03F 7/00; G03F 7/033; C08F 222/26; G03F 7/105

(52) U.S. Cl. CPC G03F 7/0007; G03F 7/033; C08F 222/26; G03F 7/105; H10K 59/12

(57) ABSTRACT

Provided are a more reliable display panel, in which decomposition is performed using a photoinitiator having a radical-forming functional group with weak binding affinity, it is decomposed at a lower temperature and the thus-formed pattern not only releases a smaller amount of outgas, but also forms a pattern with high sensitivity.

### TECHNICAL FIELD

The present disclosure relates to a photosensitive resin composition and a display device capable of realizing a clearer image using the same.

### BACKGROUND ART

A liquid crystal display (LCD) device, an organic light emitting display device (OLED), etc. are widely used as flat panel displays. Among them, the organic light emitting display device in particular has advantages such as low power consumption, fast response speed, high color reproducibility, high luminance, and a wide viewing angle.

In the case of the organic light emitting display device, a polarizing film is used to block the light reflected from the panel due to incident external light, and there is a disadvantage in that the polarizing film is not suitable for application to a flexible device due to a lack of bending properties.

As a method for solving the above problem, a method in which an inorganic film for blocking light is formed on an upper substrate as well as a color filter and a black matrix, etc. have been proposed. However, this method has a limit in obtaining a desired level of an anti-reflection effect, and does not specifically suggest a method for replacing the polarizing film.

Meanwhile, coloring patterns are used not only in liquid crystal displays but also in organic light emitting displays as red, green, and blue color filters in liquid crystal display devices.

In preparing the coloring pattern, carbon black and inorganic pigments as well as various types of organic pigments are used as colorants, and the pigment dispersion in which these pigments are dispersed is mixed with other compositions to form a pattern.

The organic light emitting display made in the pixel formed in this way can implement more vivid colors. However, the coloring pattern has a large amount of outgas, and this outgas reduces the lifespan of the display.

### DISCLOSURE

### Technical Problem

In order to solve the problems in the conventional art, one embodiment of the present disclosure is to provide a pixel with high reliability as well as vivid colors by implementing a colored pattern with a low amount of outgas on an electrode substrate.

### Technical Solution

The present disclosure provides a photosensitive resin composition which includes an alkali-soluble resin; a reactive unsaturated compound; a photoinitiator having a maximum molar absorption coefficient of 10,000 (L/mol·cm) or more in the region of 320 nm to 380 nm and a 5% weight loss that occurs at 200° C. or below; a colorant; and a solvent.

Preferably, the alkali-soluble resin includes a repeating unit represented by the following Formula (1).

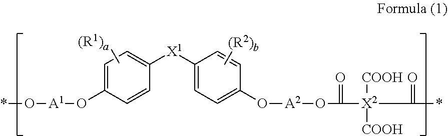

In Formula (1) above,
1) * represents a part where a bond is connected by a repeating unit,
2) R¹ and R² are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
3) R¹ and R² are each able to form a ring with a neighboring group,
4) a and b are each independently an integer of 0 to 4,
5) X¹ is a single bond, O, CO, SO₂, CR′R″, SiR′R″, Formula (A), or Formula (B),
6) X² is a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; or a combination thereof,
7) R′ and R″ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
8) R′ and R″ are each able to form a ring with a neighboring group,
9) A¹ and A² are each independently Formula (C) or Formula (D),
10) the ratio of Formula (C) to Formula (D) in a polymer chain of the resin including the repeating unit represented by Formula (1) satisfies 1:9 to 9:1,

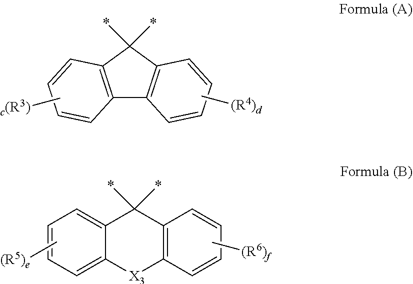

wherein in Formula (A) and Formula (B) above,
11-1) * represents a binding site,
11-2) X³ is O, S, SO₂, or NR′,
11-3) R′ is hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
11-4) R³ to R⁶ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
11-5) R³ to R⁶ are each independently able to form a ring with a neighboring group,
11-6) c to f are each independently an integer of 0 to 4,

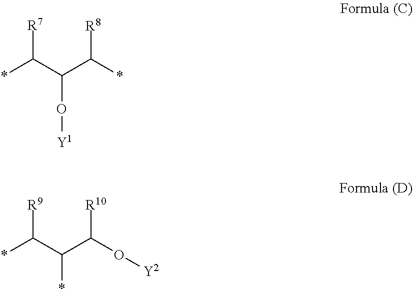

wherein in Formula (C) and Formula (D) above,
12-1) * represents a binding site,
12-2) R⁷ to R¹⁰ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
12-3) Y¹ and Y² are each independently Formula (E) or Formula (F),

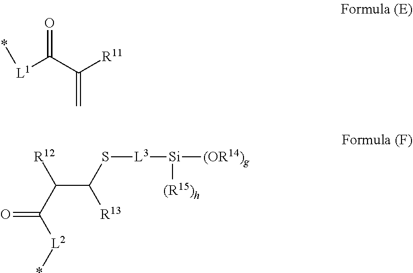

wherein in Formula (E) and Formula (F) above,
13-1) * represents a binding site,
13-2) R¹¹ to R¹⁵ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
13-3) L¹ to L³ are each independently a single bond, C₁₋₃₀ alkylene, C₆₋₃₀ arylene, or C₂₋₃₀ heterocyclic ring,
13-4) g and h are each independently an integer from 0 to 3; with the proviso that g+h=3, and
14) the R¹ to R¹⁵, R′, R″, X¹ to X², and L¹ to L³, and the ring formed by a mutual binding between the neighboring groups may each be further substituted with one or more substituents selected from the group consisting of deuterium; a halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof; or may form a ring between the neighboring substituents.

It is preferable that the weight average molecular weight of the alkali-soluble resin according to the present disclosure be in the range of 1,000 g/mol to 100,000 g/mol.

Additionally, it is preferable that the ratio of Formula (E) and Formula (F) in the polymer chain of the resin including a repeating unit represented by Formula (1) above be in the range of 2:0 to 1:1.

Additionally, it is preferable that the reactive unsaturated compound be included at 1 wt % to 40 wt % based on the total amount of the photosensitive resin composition.

Additionally, it is more preferable that the reactive unsaturated compound includes a compound represented by the following Formula (2):

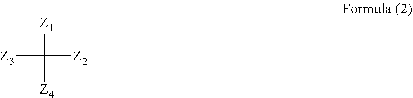

wherein in Formula (2) above, two or more of Z₁ to Z₄ have the following structure of Formula (G) to be independent of one another; and the remaining Z₁ to Z₄ are each independently hydrogen, deuterium, a halogen, a methyl group, an ethyl group; a methylhydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,

* [symbol] L₄-O [symbol] ₜY₃ Formula (G)
wherein in Formula (G) above,
1) t is an integer of 1 to 20,
2) L₄ is a single bond, a C₁₋₃₀ alkylene group, C₆₋₃₀ arylene, or C₂₋₃₀ heterocyclic ring,
3) Y₃ is the following Formula (H) or Formula (I),

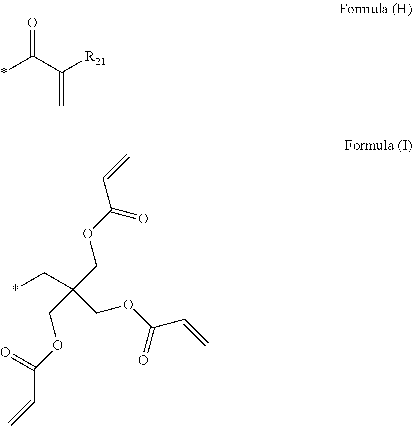

wherein in Formula (H) above, R²¹ is hydrogen, deuterium, a halogen, a methyl group, an ethyl group; a methylhydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group.

Additionally, it is preferable that the colorant be included at 5 wt % to 40 wt % based on the total amount of the photosensitive resin composition.

Additionally, it is preferable that the colorant include at least one of black, red, blue, green, yellow, purple, orange, white, silver, or gold inorganic dyes, organic dyes, inorganic pigments, and organic pigments.

Additionally, it is preferable that the photoinitiator be included at 0.01 wt % to 10 wt % based on the total amount of the photosensitive resin composition.

Additionally, it is more preferable that the reactive unsaturated compound includes a compound represented by the following Formula (3):

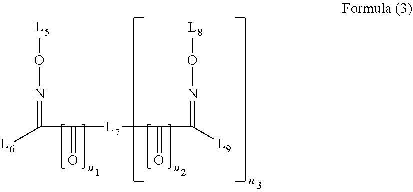

wherein in Formula (3) above,
1) u₁ to u₃ are each independently an integer of 0 or 1,
2) L₅ and L₈ are the following Formula (J),
3) L₆, L₇, and L₉ are each independently a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₃₋₃₀ alicyclic group a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; a C₁₋₂₀ alkoxycarbonyl group; a C₁₋₃₀ alkylene group; or a C₆₋₃₀ arylene, and

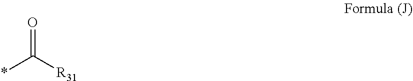

wherein in Formula (J) above, R³¹ is hydrogen, deuterium, a halogen, a methyl group, an ethyl group; a methylhydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group.

Additionally, it is preferable that L₆, L₇, and L₉ of Formula (3) above be each independently one of the following Formulas (K) to (N):

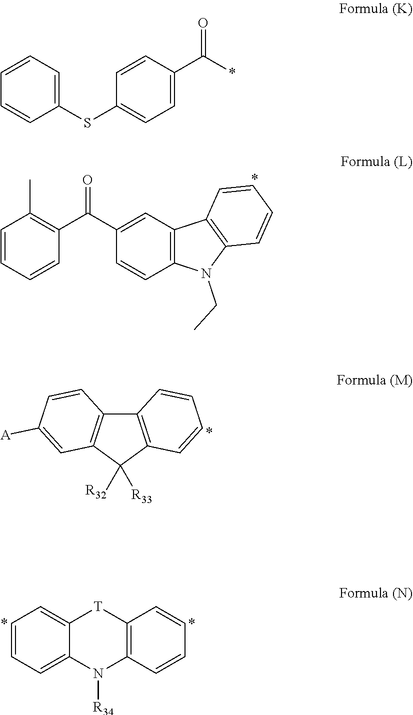

wherein in Formula (M) and Formula (N) above,
1) A is hydrogen; O; S; a silane group; a siloxane group; a boron group; a germanium group; a cyano group; a nitro group; a nitrile group; an amino group substituted or unsubstituted with a C₁₋₃₀ alkyl group, a C₆₋₃₀ aryl group, or a C₂₋₃₀ heterocyclic group; a C₁₋₃₀ alkylthio group; a C₁₋₃₉ alkyl group; a C₁₋₃₀ alkoxy group; a C₆₋₃₉ arylalkoxy group; a C₂₋₃₀ alkenyl group; a C₂-alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof,
2) R³² to R³⁴ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group, and
3) T is S, O, or Se.

Additionally, in an embodiment of the present disclosure, there is provided a pattern or film formed from the photosensitive composition according to the present disclosure.

Additionally, it is preferable that the display device according to the present disclosure include a first electrode formed on a substrate, a second electrode provided to face the first electrode, and the pattern or film formed from the photosensitive composition according to the present invention.

Additionally, it is preferable that the pattern be a color unit or color separation unit.

Additionally, it is preferable that the electronic device according to the present disclosure include the display device according to the present disclosure and a control unit for driving the display device.

### Advantageous Effects

The resin composition according to an embodiment of the present disclosure can provide a more reliable display panel, in which decomposition is performed using a photoinitiator having a radical-forming functional group with weak binding affinity, it is decomposed at a lower temperature and the thus-formed pattern not only releases a smaller amount of outgas, but also forms a pattern with high sensitivity.

### BRIEF DESCRIPTION OF THE DRAWINGS

FIGS. 1 and 2 show the measurement of a molar absorption coefficient and the temperature at which 5% weight loss occurs according to Examples and Comparative Examples of the present disclosure.

FIG. 3 schematically shows a display device according to a specific embodiment of the present disclosure.

### MODE FOR DISCLOSURE

The present disclosure provides a photosensitive resin composition which includes an alkali-soluble resin; a reactive unsaturated compound; a photoinitiator in which the maximum molar absorption coefficient in the region of 320 nm to 380 nm is 10,000 (L/mol cm) or more and a 5% weight loss that occurs at 200° C. or below; a colorant; and a solvent.

Preferably, the alkali-soluble resin includes a repeating unit represented by the following Formula (1).

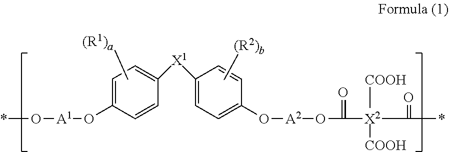

Hereinafter, some embodiments of the present disclosure will be described in detail with reference to exemplary drawings. In adding reference numerals to components of each drawing, the same component may have the same reference numeral even though they are indicated in different drawings.

When it is determined that a detailed description of a related known constitution or function may obscure the gist of the present disclosure in describing the present disclosure, the detailed description thereof may be omitted. When the expressions “includes”, “has”, “consisting of”, etc. mentioned in this specification are used, other parts may be added unless “only” is used. When a component is expressed in the singular form, it may include a case in which the plural form is included unless otherwise explicitly stated.

In describing the components of the present disclosure, terms such as first, second, A, B, (a), (b), etc. may be used. These terms are only for distinguishing the components from other components, and the essence, order, sequence, the number, etc. of the components are not limited by the terms.

In the description of the positional relationship of the components, when two or more components are described as being “connected”, “linked”, or “fused”, etc., the two or more components may be directly “connected”, “linked”, or “fused”, but it should be understood that the two or more components may also be “connected”, “linked”, or “fused” by way of a further “interposition” of a different component. In particular, the different component may be included in any one or more of the two or more components that are to be “connected”, “linked”, or “fused” to each other.

In addition, when a component (e.g., a layer, a film, a region, a plate, etc.) is described to be “on top” or “on” of another component, it should be understood that this may also include a case where another component is “immediately on top of” as well as a case where another component is disposed therebetween. In contrast, it should be understood that when a component is described to be “immediately on top of” another component, it should be understood that there is no other component disposed therebetween.

In the description of the temporal flow relationship related to the components, the operation method, or the production method, for example, when the temporal precedence or flow precedence is described by way of “after”, “subsequently”, “thereafter”, “before”, etc., it may also include cases where the flow is not continuous unless terms such as “immediately” or “directly” are used.

Meanwhile, when the reference is made to numerical values or corresponding information for components, numerical values or corresponding information may be interpreted as including an error range that may occur due to various factors (e.g., procedural factors, internal or external shocks, noise, etc.) even if it is it not explicitly stated.

The terms used in this specification and the appended claims are as follows, unless otherwise stated, without departing from the spirit of the present disclosure.

As used herein, the term “halo” or “halogen” includes fluorine (F), chlorine (Cl), bromine (Br), and iodine (I), unless otherwise specified.

As used herein, the term “alkyl” or “alkyl group” has 1 to 60 carbons linked by a single bond unless otherwise specified, and refers to a radical of a saturated aliphatic functional group, including a linear chain alkyl group, a branched chain alkyl group, a cycloalkyl (alicyclic) group, an alkyl-substituted cycloalkyl group, and a cycloalkyl-substituted alkyl group.

As used herein, the term “haloalkyl group” or “halogenalkyl group” refers to an alkyl group in which a halogen is substituted, unless otherwise specified.

As used herein, the term “alkenyl” or “alkynyl” has a double bond or a triple bond, respectively, includes a linear or branched chain group, and has 2 to 60 carbon atoms, unless otherwise specified, but is not limited thereto.

As used herein, the term “cycloalkyl” refers to an alkyl which forms a ring having 3 to 60 carbon atoms unless otherwise specified, but is not limited thereto.

As used herein, the term “an alkoxy group” or “alkyloxy group” refers to an alkyl group to which an oxygen radical is linked, and has 1 to 60 carbon atoms unless otherwise specified, but is not limited thereto.

As used herein, the term “alkenoxyl group”, “alkenoxy group”, “alkenyloxyl group”, or “alkenyloxy group” refers to an alkenyl group to which an oxygen radical is linked, and has 2 to 60 carbon atoms unless otherwise specified, but is not limited thereto.

As used herein, the terms “aryl group” and “arylene group” each have 6 to 60 carbon atoms unless otherwise specified, but are not limited thereto. As used herein, the aryl group or arylene group includes a single ring type, a ring assembly, a fused multiple ring compound, etc. For example, the aryl group may include a phenyl group, a monovalent functional group of biphenyl, a monovalent functional group of naphthalene, a fluorenyl group, and a substituted fluorenyl group, and the arylene group may include a fluorenylene group and a substituted fluorenylene group.

As used herein, the term “ring assembly” means that two or more ring systems (monocyclic or fused ring systems) are directly connected to each other through a single bond or double bond, in which the number of direct links between such rings is one less than the total number of ring systems in the compound. In the ring assembly, the same or different ring systems may be directly connected to each other through a single bond or double bond.

As used herein, since the aryl group includes a ring aggregate, the aryl group includes biphenyl and terphenyl in which a benzene ring, which is a single aromatic ring, is connected by a single bond. In addition, since the aryl group also includes a compound in which an aromatic ring system fused to an aromatic single ring is connected by a single bond, it also includes, for example, a compound in which a benzene ring (which is a single aromatic ring) and fluorine (which is a fused aromatic ring system) are linked by a single bond.

As used herein, the term “fused multiple ring system” refers to a fused ring form in which at least two atoms are shared, and it includes a form in which ring systems of two or more hydrocarbons are fused, a form in which at least one heterocyclic system including at least one heteroatom is fused, etc. Such a fused multiple ring system may be an aromatic ring, a heteroaromatic ring, an aliphatic ring, or a combination of these rings. For example, in the case of an aryl group, it may be a naphthalenyl group, a phenanthrenyl group, a fluorenyl group, etc., but is not limited thereto.

As used herein, the term “a spiro compound” has a spiro union, and the spiro union refers to a linkage in which two rings share only one atom. In particular, the atom shared by the two rings is called a “spiro atom”, and they are each called “monospiro-”, “dispiro-”, and “trispiro-” compounds depending on the number of spiro atoms included in a compound.

As used herein, the terms “fluorenyl group”, “fluorenylene group”, and “fluorenetriyl group” refer to a monovalent, divalent, or trivalent functional group in which R, R′, R″, and R′″ are all hydrogen in the following structures, respectively, unless otherwise specified; “substituted fluorenyl group”, “substituted fluorenylene group”, or “substituted fluorenetriyl group” means that at least one of the substituents R, R′, R″, and R′″ is a substituent other than hydrogen, and includes cases where R and R′ are bound to each other to form a spiro compound together with the carbon to which they are linked. As used herein, all of the fluorenyl group, the fluorenylene group, and the fluorenetriyl group may also be referred to as a fluorene group regardless of valences such as monovalent, divalent, trivalent, etc.

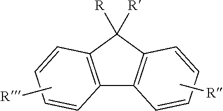

In addition, the R, R′, R″, and R′″ may each independently be an alkyl group having 1 to 20 carbon atoms, an alkenyl group having 1 to 20 carbon atoms, an aryl group having 6 to carbon atoms, and a heterocyclic group having 2 to 30 carbon atoms and, for example, the aryl group may be phenyl, biphenyl, naphthalene, anthracene, or phenanthrene, and the heterocyclic group may be pyrrole, furan, thiophene, pyrazole, imidazole, triazole, pyridine, pyrimidine, pyridazine, pyrazine, triazine, indole, benzofuran, quinazoline, or quinoxaline. For example, the substituted fluorenyl group and the fluorenylene group may each be a monovalent functional group or divalent functional group of 9,9-dimethylfluorene, 9,9-diphenylfluorene and 9,9′-spirobi[9H-fluorene].

As used herein, the term “heterocyclic group” includes not only aromatic rings (e.g., “heteroaryl group” and “heteroarylene group”), but also non-aromatic rings, and may refer to a ring having 2 to 60 carbon atoms each including one or more heteroatoms unless otherwise specified, but is not limited thereto. As used herein, the term “heteroatom” refers to N, O, S, P, or Si unless otherwise specified, and a heterocyclic group refers to a monocyclic group including a heteroatom, a ring assembly, a fused multiple ring system, a spiro compound, etc.

For example, the “heterocyclic group” may include a compound including a heteroatom group (e.g., SO₂, P═O, etc.), such as the compound shown below, instead of carbon that forms a ring.

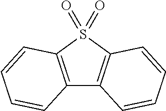 [SMILES: O=S1(=O)c2ccccc2-c2ccccc21]

As used herein, the term “ring” includes monocyclic and polycyclic rings, and includes heterocycles containing at least one heteroatom as well as hydrocarbon rings, and includes aromatic and non-aromatic rings.

As used herein, the term “polycyclic” includes ring assemblies (e.g., biphenyl, terphenyl, etc.), fused multiple ring systems, and spiro compounds, includes non-aromatic as well as aromatic compounds, and includes heterocycles containing at least one heteroatom as well as hydrocarbon rings.

As used herein, the term “alicyclic group” refers to cyclic hydrocarbons other than aromatic hydrocarbons, and it includes monocyclic, ring assemblies, fused multiple ring systems, spiro compounds, etc., and refers to a ring having 3 to 60 carbon atoms unless otherwise specified, but is not limited thereto. For example, when benzene (i.e., an aromatic ring) and cyclohexane (i.e., a non-aromatic ring) are fused, it also corresponds to an aliphatic ring.

Additionally, when prefixes are named consecutively, it means that the substituents are listed in the order they are described. For example, in the case of an arylalkoxy group, it means an alkoxy group substituted with an aryl group; in the case of an alkoxycarbonyl group, it means a carbonyl group substituted with an alkoxy group; additionally, in the case of an arylcarbonyl alkenyl group, it means an alkenyl group substituted with an arylcarbonyl group, in which the arylcarbonyl group is a carbonyl group substituted with an aryl group.

Additionally, unless otherwise specified, the term “substituted” in the expression “substituted or unsubstituted” as used herein refers to a substitution with one or more substituents selected from the group consisting of deuterium, a halogen, an amino group, a nitrile group, a nitro group, a C₁₋₂₀ alkyl group, a C₁₋₂₀ alkoxy group, a C₁₋₂₀ alkylamine group, a C₁₋₂₀ alkylthiophene group, a C₆₋₂₀ arylthiophene group, a C₂₋₂₀ alkenyl group, a C₂₋₂₀ alkynyl group, a C₃₋₂₀ cycloalkyl group, a C₆₋₂₀ aryl group, a C₆₋₂₀ aryl group substituted with deuterium, a C₈₋₂₀ arylalkenyl group, a silane group, a boron group, a germanium group, and a C₂₋₂₀ heterocyclic group containing at least one heteroatom selected from the group consisting of O, N, S, Si, and P, but is not limited to these substituents.

As used herein, the “names of functional groups” corresponding to the aryl group, arylene group, heterocyclic group, etc. exemplified as examples of each symbol and a substituent thereof may be described as “a name of the functional group reflecting its valence”, and may also be described as the “name of its parent compound”. For example, in the case of “phenanthrene”, which is a type of an aryl group, the names of the groups may be described such that the monovalent group is described as “phenanthryl (group)”, and the divalent group is described as “phenanthrylene (group)”, etc., but may also be described as “phenanthrene”, which is the name of its parent compound, regardless of its valence.

Similarly, in the case of pyrimidine as well, it may be described regardless of its valence, or in the case of being monovalent, it may be described as pyrimidinyl (group); and in the case of being divalent, it may be described as the “name of the group” of the valence (e.g., pyrimidinylene (group)). Therefore, as used herein, when the type of a substituent is described as the name of its parent compound, it may refer to an n-valent “group” formed by detachment of a hydrogen atom linked to a carbon atom and/or hetero atom of its parent compound.

In addition, in describing the names of the compounds or the substituents in the present specification, the numbers, letters, etc. indicating positions may be omitted. For example, pyrido[4,3-d]pyrimidine may be described as pyridopyrimidine; benzofuro[2,3-d]pyrimidine as benzofuropyrimidine; 9,9-dimethyl-9H-fluorene as dimethylfluorene, etc. Therefore, both benzo[g]quinoxaline and benzo[f]quinoxaline may be described as benzoquinoxaline.

In addition, unless there is an explicit description, the formulas used in the present disclosure are applied in the same manner as in the definition of substituents by the exponent definition of the formula below.

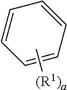

In particular, when a is an integer of 0, it means that the substituent R¹ is absent, that is, when a is 0, it means that all hydrogens are linked to carbons that form a benzene ring, and in this case, the formula or compound may be described while omitting the indication of the hydrogen linked to the carbon. In addition, when a is an integer of 1, one substituent R¹ may be linked to any one of the carbons forming a benzene ring; when a is an integer of 2 or 3, it may be linked, for example, as shown below; even when a is an integer of 4 to 6, it may be linked to the carbon of a benzene ring in a similar manner; and when a is an integer of 2 or greater, R¹ may be the same as or different from each other.

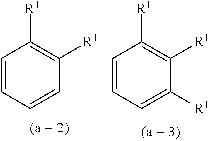

Unless otherwise specified in the present application, forming a ring means that neighboring groups bind to one another to form a single ring or fused multiple ring, and the single ring and the formed fused multiple ring include a heterocycle containing at least one heteroatom as well as a hydrocarbon ring, and may include aromatic and non-aromatic rings.

In addition, unless otherwise specified in the present specification, when indicating a condensed ring, the number in “number-condensed ring” indicates the number of rings to be condensed. For example, a form in which three rings are condensed with one another (e.g., anthracene, phenanthrene, benzoquinazoline, etc.) may be expressed as a 3-condensed ring.

Meanwhile, as used herein, the term “bridged bicyclic compound” refers to a compound in which two rings share 3 or more atoms to form a ring, unless otherwise specified. In particular, the shared atoms may include carbon or a hetero atom.

In the present disclosure, an organic electric device may refer to a component(s) between an anode and a cathode, or may refer to an organic light emitting diode which includes an anode, a cathode, and a component(s) disposed therebetween.

Additionally, in some cases, the display device in the present disclosure may refer to an organic electric device, an organic light emitting diode, and a panel including the same, or may refer to an electronic device including a panel and a circuit. In particular, for example, the electronic device may include a lighting device, a solar cell, a portable or mobile terminal (e.g., a smart phone, a tablet, a PDA, an electronic dictionary, a PMP, etc.), a navigation terminal, a game machine, various TV sets, various computer monitors, etc., but is not limited thereto, and may be any type of device as long as it includes the component(s).

Hereinafter, embodiments of the present disclosure will be described in detail. However, these embodiments are provided for illustrative purposes, and the present disclosure is not limited thereby, and the present disclosure is only defined by the scope of the claims to be described later. Hereinafter, each component will be described in detail.

The photosensitive resin composition according to an embodiment of the present disclosure includes an alkali-soluble resin; a reactive unsaturated compound; a photoinitiator in which the maximum molar absorption coefficient in the region of 320 nm to 380 nm is 10,000 (L/mol·cm) or more and a 5% weight loss occurs at 200° C. or below; a colorant; and a solvent.

Preferably, the alkali-soluble resin includes a repeating unit represented by the following Formula (1).

(1) Alkali Soluble Resin

The binder resin according to an embodiment of the present disclosure includes a repeating unit with the structure of the following Formula (1).

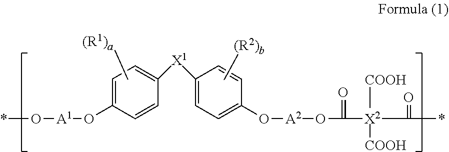

wherein in Formula (1) above,
1) * represents a part where a bond is connected by a repeating unit,
R¹ and R² are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
3) R¹ and R² are each able to form a ring with a neighboring group,
4) a and b are each independently an integer of 0 to 4,
5) X¹ is a single bond, O, CO, SO₂, CR′R″, SiR′R″, Formula (A), or Formula (B); preferably Formula (A) or Formula (B); and more preferably Formula (A),
6) X² is a C₆₋₃₀ aryl group; a C₂₋₃₀ heterocyclic group containing at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; or a combination thereof,
7) R′ and R″ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
8) R′ and R″ are each able to form a ring with a neighboring group,
9) A¹ and A² are each independently Formula (C) or Formula (D),
10) the ratio of Formula (C) to Formula (D) in a polymer chain of the resin including the repeating unit represented by Formula (1) satisfies 1:9 to 9:1.

Examples in which R′ and R″ combine with each other to form a ring are as follows.

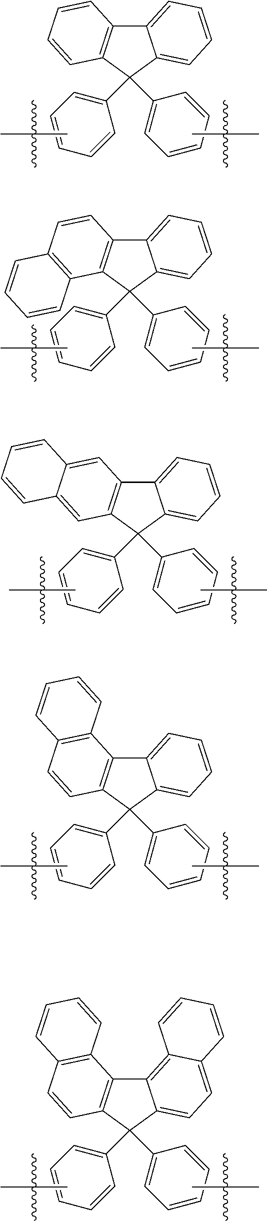

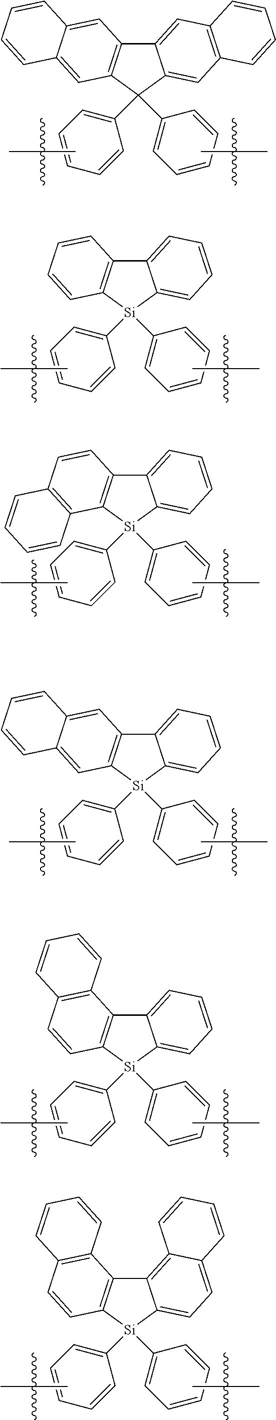

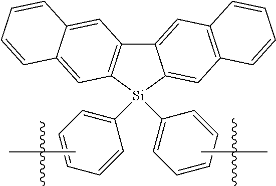

Specific embodiments in which R′ and R″ combine with each other to form a ring are as follows.

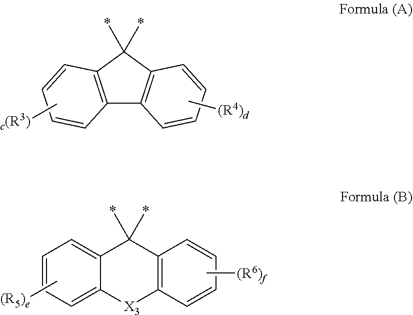

In Formula (A) and Formula (B) above,
11-1) * represents a binding site,
11-2) X³ is O, S, SO₂, or NR′,
11-3) R′ is hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
11-4) R³ to R⁶ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
11-5) R³ to R⁶ are each independently able to form a ring with a neighboring group, and
11-6) c to f are each independently an integer of 0 to 4.

Specific embodiments of the above-mentioned Formulas (C) and (D) are as follows.

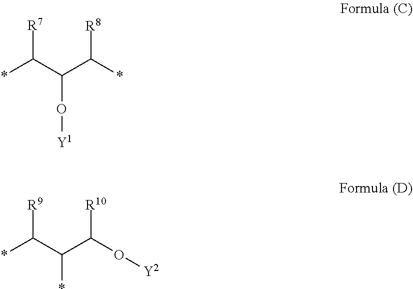

wherein in Formula (C) and Formula (D) above,
12-1) * represents a binding site,
12-2) R⁷ to R¹⁶ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group, and
12-3) Y¹ and Y² are each independently Formula (E) or Formula (F).

Specific embodiments of the above-mentioned Formulas (E) and (F) are as follows.

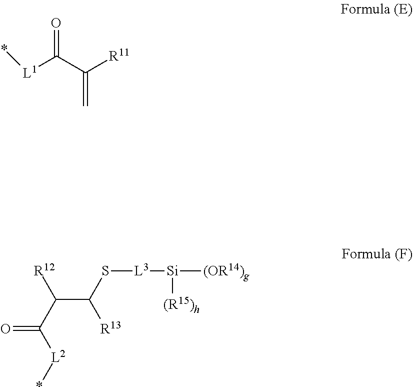

In Formula (E) and Formula (F) above,
13-1) * represents a binding site,
13-2) R¹¹ to R¹⁵ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
13-3) L¹ to L³ are each independently a single bond, C₁₋₃₀ alkylene, C₆₋₃₀ arylene, or C₂₋₃₀ heterocyclic ring,
13-4) g and h are each independently an integer from 0 to 3; with the proviso that g+h=3, and
14) the R¹ to R¹⁵, R′, R″, X¹ to X², and L¹ to L³, and the ring formed by a mutual binding between the neighboring groups may each be further substituted with one or more substituents selected from the group consisting of deuterium; a halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof; or may form a ring between the neighboring substituents.

When the R¹ to R¹⁵, R′, R″, and X¹ to X² are an aryl group, they may preferably be a C₆₋₃₀ aryl group, and more preferably a C₆₋₁₈ aryl group (e.g., phenyl, biphenyl, naphthyl, terphenyl, etc.).

When the R¹ to R¹⁵, R′, R″, X¹ to X², and L¹ to L³ are a heterocyclic group, they may preferably be a C₂₋₃₀ heterocyclic group, and more preferably a C₂₋₁₈ heterocyclic group (e.g., dibenzofuran, dibenzothiophene, naphthobenzothiophene, naphthobenzofuran, etc.).

When the R¹ to R¹⁵, R′, R″, and X¹ to X² are a fluorenyl group, they may preferably be 9,9-dimethyl-9H-fluorene, a 9,9-diphenyl-9H-fluorenyl group, 9,9′-spirobifluorene, etc.

When the L¹ to L³ are an arylene group, they may preferably be a C₆₋₃₀ arylene group, and more preferably a C₆₋₁₈ arylene group (e.g., phenyl, biphenyl, naphthyl, terphenyl, etc.).

When the R¹ to R¹⁵, R′, and R″ are an alkyl group, they may preferably be a C₁₋₁₀ alkyl group (e.g., methyl, t-butyl, etc.).

When the R¹ to R¹⁵, R′, and R″ are an alkoxyl group, they may preferably be a C₁₋₂₀ alkoxyl group, and more preferably a C₁₋₁₀ alkoxyl group (e.g., methoxy, t-butoxy, etc.).

The ring formed by binding to one another among the neighboring groups of the R¹ to R¹⁵, R′, R″, X¹ to X², and L¹ to L³ may be a C₆₋₆₀ aromatic ring group; a fluorenyl group; a C₂₋₆₀ heterocyclic group including at least one heteroatom among O, N, S, Si, and P; or a C₃₋₆₀ aliphatic ring group, and for example, when an aromatic ring is formed by a mutual binding between the neighboring groups, preferably a C₆₋₂₀ aromatic ring, and more preferably a C₆₋₁₄ aromatic ring (e.g., benzene, naphthalene, phenanthrene, etc.) may be formed.

The ratio of Formula (E) and Formula (F) in the polymer chain of the resin including the repeating unit represented by Formula (1) is preferably 2:0 to 1:1, and most preferably 1.5:0.5. When the ratio of Formula (F) is higher than the ratio of Formula (E), a residue may be generated due to the too high adhesion, and the amount of outgas generated may also be significantly increased, and when the ratio of Formula (E) to Formula (F) is 1.5:0.5, the resolution of the pattern is the best and the amount of outgas can be satisfied.

The weight average molecular weight of the resin of the present disclosure may be 1,000 g/mol to 100,000 g/mol, preferably 1,000 to 50,000 g/mol, and more preferably 1,000 to g/mol. When the weight average molecular weight of the resin is within the above range, the pattern can be well formed without a residue when the pattern layer is prepared, there is no loss of film thickness during development, and a good pattern can be obtained.

The resin may be included in an amount of 1 wt % to 30 wt %, more preferably 3 wt % to 20 wt % based on the total amount of the photosensitive resin composition.

When the resin is included within the above range, excellent sensitivity, developability, and adhesion (an adherent property) can be obtained.

The photosensitive resin composition may further include an acrylic resin in addition to the resin. The acrylic resin is a copolymer of a first ethylenically unsaturated monomer and a second ethylenically unsaturated monomer copolymerizable therewith, and may be a resin including one or more acrylic repeating units.

(2) Reactive Unsaturated Compound

The photosensitive resin composition according to an embodiment of the present disclosure includes a reactive unsaturated compound having a structure as shown in Formula (2) below.

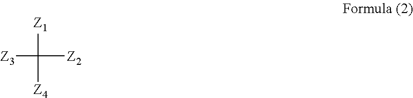

In Formula (2) above, two or more of Z₁ to Z₄ have the following structure of Formula (G) to be independent of one another; and the remaining Z₁ to Z₄ are each independently hydrogen, deuterium, a halogen, a methyl group, an ethyl group; a methylhydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group.

A specific embodiment of the above-mentioned Formula (G) is as follows.

* [symbol] L₄-O [symbol] ₜY₃ Formula (G)

In Formula (G) above,
1) t is an integer of 1 to 20,
L₄ is a single bond, a C₁₋₃₀ alkylene group, C₆₋₃₀ arylene, or C₂₋₃₀ heterocyclic ring,
Y₃ is the following Formula (H) or Formula (I),

Specific examples of the above-mentioned Formula (H) or Formula (I) are as follows.

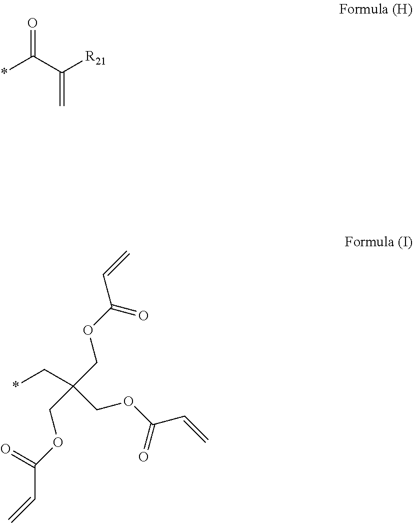

In Formula (H) above, R²¹ is hydrogen, deuterium, a halogen, a methyl group, an ethyl group; a methylhydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆-aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group.

The multi-acrylic compound having the structure as in Formula (2) may be used alone or in combination of two or more. Examples thereof include polyfunctional esters of (meth)acrylic acid having at least two ethylenically unsaturated double bonds.

In the present specification, “(meth)acrylic acid” may refer to methacrylic acid, acrylic acid, or a mixture of methacrylic acid and acrylic acid.

Since the reactive unsaturated compound has the ethylenically unsaturated double bond, it is possible to form a pattern having excellent heat resistance, light resistance, and chemical resistance by causing sufficient polymerization during exposure to light in the pattern forming process.

Specific examples of the reactive unsaturated compound may be one or more selected among ethylene glycol diacrylate, ethylene glycol dimethacrylate, diethylene glycol diacrylate, triethylene glycol diacrylate, triethylene glycol dimethacrylate, 1,6-hexanediol diacrylate, 1,6-hexanediol dimethacrylate, pentaerythritol triacrylate, dipentaerythritol pentaacrylate, dipentaerythritol hexaacrylate, bisphenol A epoxy acrylate, ethylene glycol monomethyl ether acrylate, and trimethylolpropane triacrylate but is not limited thereto.

Examples of commercially available products of the reactive unsaturated compound are as follows.

Examples of the bifunctional ester of (meth)acrylic acid may include Aronix M-210, M-240, M-6200, etc. (Toa Kosei Kagaku Kogyo Co., Ltd.), KAYARAD HDDA, HX-220, R-604, etc. (Nippon Kayaku Co., Ltd.), and V-260, V-312, V-335 HP, etc. (Osaka Yuki Kagaku Kogyo Co., Ltd.).

Examples of the trifunctional ester of (meth)acrylic acid include M-309, M-400, M-405, M-450, M-7100, M-8030, and M-8060 (Toa Kosei Kagaku Kogyo Co., Ltd.), KAYARAD TMPTA, DPCA-20, DPCA-60, DPCA-120, etc. (Nippon Kayaku Co., Ltd.), and V-295, V-300, V-360, etc. (Osaka Yuki Kagaku Kogyo Co., Ltd.).

These products may be used alone or in combination of two or more.

The reactive unsaturated compound may be used after an acid anhydride treatment so as to provide improved developability. The reactive unsaturated compound may be included in an amount of 1 wt % to 40 wt %, for example, 1 wt % to 20 wt %, based on the total amount of the photosensitive composition. When the reactive unsaturated compound is included within the above range, sufficient curing occurs during exposure to light in the pattern forming process, thus obtaining excellent reliability, excellent heat resistance, light resistance, and chemical resistance of the pattern, and also excellent resolution and adhesion.

(3) Photoinitiators

In order to implement a negative pattern by photolithography, it is necessary to use a photoradical initiator. The photoinitiator is a photoinitiator having a maximum molar absorption coefficient in the region of 320 nm to 380 nm of 10,000 (L/mol·cm) or more and a 5% weight loss that occurs at 200° C. or below. In particular, the maximum molar absorption coefficient in the region of 320 nm to 380 nm may be calculated by the Beer-Lambert Law. In addition, weight loss was measured while increasing the temperature to 300° C. at a rate of 5° C. per minute in a nitrogen atmosphere using TGA.

The photosensitive resin composition according to an embodiment of the present disclosure includes a photoinitiator having a structure as shown in the following Formula (3).

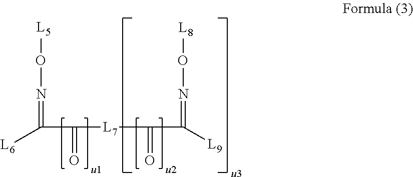

In Formula (3) above,
1) u₁ to u₃ are each independently an integer of 0 or 1,
2) L₅ and L₈ are the following Formula (J),
3) L₆, L₇, and L₉ are each independently a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₃₋₃₀ alicyclic group a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; a C₁₋₂₀ alkoxycarbonyl group; a C₁₋₃₀ alkylene group; or a C₆₋₃₀ arylene.

A specific embodiment of the above-mentioned Formula (J) is as follows.

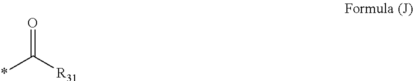

In Formula (J) above, R³¹ is hydrogen, deuterium, a halogen, a methyl group, an ethyl group; a methylhydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆-aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group.

In addition, it is more preferable that L₆, L₇, and L₉ of Formula (3) are each independently one of the following Formulas (K) to (N).

Specific examples of the above-mentioned Formulas (K) to (N) are as follows.

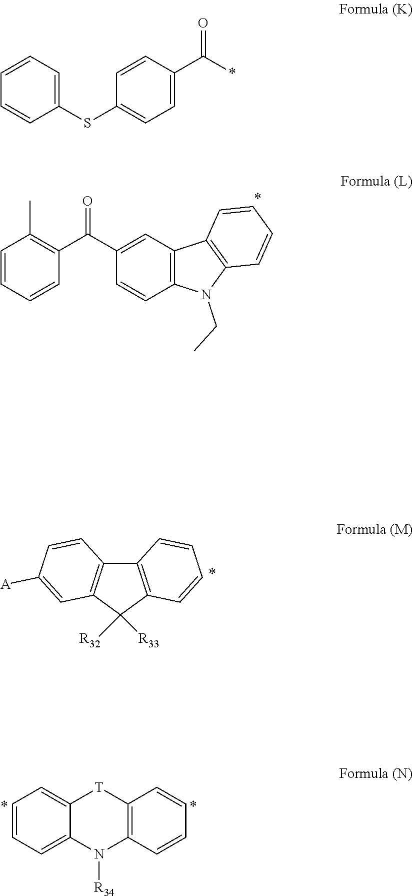

In Formula (M) and Formula (N) above,
1) A is hydrogen; O; S; a silane group; a siloxane group; a boron group; a germanium group; a cyano group; a nitro group; a nitrile group; an amino group substituted or unsubstituted with a C₁₋₃₀ alkyl group, a C₆₋₃₀ aryl group, or a C₂₋₃₀ heterocyclic group; a C₁₋₃₀ alkylthio group; a C₁₋₃₀ alkyl group; a C₁₋₃₀ alkoxy group; a C₆₋₃₀ arylalkoxy group; a C₂₋₃₀ alkenyl group; a C₂-alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof,
2) R³² to R³⁴ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group, and
3) T is S, O, or Se.

In the photosensitive resin composition according to an embodiment of the present disclosure, the oxime ester-based compound of Formula (3) above may be used alone or in combination of two or more.

The initiator that can be used in combination with the oxime ester-based compound is an initiator used in the photosensitive resin composition, and examples of the initiator may include an acetophenone-based compound, a benzophenone-based compound, a thioxanthone-based compound, a benzoin-based compound, a triazine-based compound, etc.

Examples of the acetophenone-based compound may include 2,2′-diethoxy acetophenone, 2,2′-dibutoxy acetophenone, 2-hydroxy-2-methylpropiophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethyl amino-1-(4-morpholinophenyl)-butan-1-one, etc.

Examples of the benzophenone-based compound may include benzophenone, benzoyl benzoate, methyl benzoyl benzoate, 4-phenyl benzophenone, hydroxy benzophenone, acrylated benzophenone, 4,4′-bis(dimethylamino)benzophenone, 4,4′-bis(diethylamino)benzophenone, 4,4′-dimethylaminobenzophenone, 4,4′-dichlorobenzophenone, 3,3′-dimethyl-2-methoxybenzophenone, etc.

Examples of the thioxanthone-based compound may include thioxanthone, 2-chlorothioxanthone, 2-methylthioxanthone, isopropyl thioxanthone, 2,4-diethyl thioxanthone, 2,4-diisopropyl thioxanthone, 2-chlorothioxanthone, etc.

Examples of the benzoin-based compound may include benzoin, benzoin methyl ether, benzoin ethyl ether, benzoin isopropyl ether, benzoin isobutyl ether, benzyldimethyl ketal, etc.

Examples of the triazine-based compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine; 2-biphenyl 4,6-bis(trichloromethyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-trichloromethyl(piperonyl)-6-triazine, 2-4-trichloromethyl(4′-methoxystyryl)-6-triazine, etc.

As the initiator, a carbazole-based compound, a diketone-based compound, a sulfonium borate-based compound, a diazo-based compound, an imidazole-based compound, or a biimidazole-based compound may be used in addition to the above compounds.

As the initiator, which is a radical polymerization initiator, a peroxide-based compound, an azobis-based compound, etc. may be used.

Examples of the peroxide-based compound may include ketone peroxides (e.g., methyl ethyl ketone peroxide, methyl isobutyl ketone peroxide, cyclohexanone peroxide, methylcyclohexanone peroxide, acetylacetone peroxide, etc.); diacyl peroxides (e.g., isobutyryl peroxide, 2,4-dichlorobenzoyl peroxide, o-methylbenzoyl peroxide, bis-3,5,5-trimethylhexanoyl peroxide, etc.); hydroperoxides (e.g., 2,4,4,-trimethylpentyl-2-hydroperoxide, diisopropylbenzene hydroperoxide, cumene hydroperoxide, t-butyl hydroperoxide, etc.); dialkyl peroxides (e.g., dicumyl peroxide, 2,5-dimethyl-2,5-di(t-butylperoxy)hexane, 1,3-bis(t-butyloxyisopropyl)benzene, t-butylperoxyvalerate n-butyl ester, etc.); alkyl peresters (e.g., 2,4,4-trimethylpentyl peroxyphenoxy acetate, α-cumyl peroxyneodecanoate, t-butyl peroxybenzoate, di-t-butyl peroxytrimethyl adipate, etc.); percarbonates (e.g., di-3-methoxybutyl peroxydicarbonate, di-2-ethylhexyl peroxydicarbonate, bis-4-t-butylcyclohexyl peroxydicarbonate, diisopropyl peroxydicarbonate, acetylcyclohexylsulfonyl peroxide, t-butyl peroxyaryl carbonate, etc.), etc.

Examples of the azobis-based compound may include 1,1′-azobiscyclohexan-1-carbonitrile, 2,2′-azobis(2,4-dimethylvaleronitrile), 2,2,-azobis(methylisobutyrate), 2,2′-azobis(4-methoxy-2,4-dimethylvaleronitrile), α,α′-azobis(isobutylnitrile), 4,4′-azobis(4-cyanovaleric acid), etc.

The photoinitiator may be used together with a photosensitizer that causes a chemical reaction by absorbing light to enter an excited state and then transferring the energy. Examples of the photosensitizer may include tetraethylene glycol bis-3-mercaptopropionate, pentaerythritol tetrakis-3-mercaptopropionate, dipentaerythritol tetrakis-3-mercaptopropionate, etc.

The maximum molar absorption coefficient in the region of 320 nm to 380 nm of the photoinitiator is preferably 10,000 (L/mol·cm) or more, more preferably 5,000 (L/mol·cm) to 40,000 (L/mol·cm). When the maximum molar absorption coefficient in the region of 320 nm to 380 nm of the photoinitiator is 5,000 (L/mol·cm) to 40,000 (L/mol·cm), there is an advantage of having excellent patternability due to high sensitivity. In contrast, when the maximum molar absorption coefficient in the region of 320 nm to 380 nm is less than 5,000 (L/mol cm), there is a problem in that the pattern is not properly formed in the exposure step due to low sensitivity, whereas when it exceeds 40,000 (L/mol cm), it is difficult to control the pattern size and the hole size by adjusting the exposure amount in the exposure step.

The temperature of the photoinitiator at which a 5% weight loss occurs is preferably 200° C. or below, and more preferably 150° C. to 200° C. When the temperature of the photoinitiator at which the 5% weight loss occurs is 150° C. to 200° C., there is an advantage in that a low outgas is shown in the finally formed pattern, whereas when the temperature is below 150° C., there is a problem in storage stability, and when the temperature is 200° C. or higher, there is a visible problem of showing low reliability due to high outgas.

The photoinitiator may be included in an amount of 0.01 wt % to 10 wt %, for example, wt % to 5 wt %, based on the total amount of the photosensitive resin composition. When the photoinitiator is included within the above range, it is possible to obtain excellent reliability due to sufficient curing that occurs during exposure to light in the pattern forming process, thereby obtaining excellent heat resistance, light resistance, and chemical resistance of the pattern, and also obtaining excellent resolution and adhesion, and being capable of preventing a decrease in transmittance due to an unreacted initiator.

(4) Colorant

In order to color the pattern, colorants such as pigments and dyes may be used independently or together, and both organic pigments and inorganic pigments can be used as the pigments.

The pigments include a red pigment, a green pigment, a blue pigment, a yellow pigment, a black pigment, etc. The pigments may be used alone or in combination of two or more, and the examples are not limited thereto.

Examples of the red pigment may include C.I. Red pigment 254, C.I. Red pigment 255, C.I. Red pigment 264, C.I. Red pigment 270, C.I. Red pigment 272, C.I. Red pigment 177, C.I. Red pigment 89, etc.

Examples of the green pigment may include halogen-substituted copper phthalocyanine pigments such as C.I. Green pigment 36, C.I. Green pigment 7, etc.

Examples of the blue pigment may include copper phthalocyanine pigments such as C.I. Blue pigment 15:6, C.I. Blue pigment 15, C.I. Blue pigment 15:1, C.I. Blue pigment 15:2, C.I. Blue pigment 15:3, C.I. Blue pigment 15:4, C.I. Blue pigment 15:5, and C.I. Blue pigment 16.

Examples of the yellow pigment may include C.I. isoindoline-based pigments such as Yellow pigment 139, C.I. quinophthalone-based pigments such as Yellow pigment 138, and C.I. nickel complex pigments such as C.I. Yellow pigment 150.

Examples of the black pigment may include benzofuranone black, lactam black, aniline black, perylene black, titanium black, carbon black, etc.

A dispersant may be used together to disperse the pigment in the photosensitive resin composition. Specifically, the pigment may be surface-treated in advance with a dispersant and used, or may be used by adding a dispersant together with the pigment when preparing the photosensitive resin composition. As the dispersant, a non-ionic dispersant, an anionic dispersant, a cationic dispersant, etc. may be used.

Specific examples of the dispersant may include polyalkylene glycol and an ester thereof, polyoxyalkylene, a polyalcohol ester alkylene oxide adduct, an alcohol alkylene oxide adduct, a sulfonic acid ester, a sulfonic acid salt, a carboxylic acid ester, a carboxylic acid salt, an alkylamide alkylene oxide adduct, an alkyl amine, etc., and these may be used alone or in combination of two or more.

Examples of commercially available products of the dispersant include DISPERBYK-101, DISPERBYK-130, DISPERBYK-140, DISPERBYK-160, DISPERBYK-161, DISPERBYK-162, DISPERBYK-163, DISPERBYK-164, DISPERBYK-165, DISPERBYK-166, DISPERBYK-170, DISPERBYK-171, DISPERBYK-182, DISPERBYK-2000, DISPERBYK-2001, etc., by BYK; EFKA-47, EFKA-47EA, EFKA-48, EFKA-49, EFKA-100, EFKA-400, EFKA-450 by BASF; and Solsperse 5000, Solsperse 12000, Solsperse 13240, Solsperse 13940, Solsperse 17000, Solsperse 20000, Solsperse 24000GR, Solsperse 27000, Solsperse 28000, etc. by Zeneka; or PB711, PB821, etc. by Ajinomoto.

The dispersant may be included in an amount of 0.1 wt % to 15 wt % based on the total amount of the photosensitive resin composition. When the dispersant is included within the above range, the dispersibility of the photosensitive resin composition is excellent, and thus, stability, developability and patternability are excellent in preparing the light blocking layer.

The pigment may be used after pretreatment using a water-soluble inorganic salt and a wetting agent. When the pigment is pretreated as described above and used, the primary particle size of the pigment can be refined. The pretreatment may be performed by kneading the pigment with a water-soluble inorganic salt and a wetting agent, and filtering and washing the pigment obtained in the kneading step. The kneading may be performed at a temperature of 40° C. to 100° C., and the filtration and washing may be performed by filtration after washing the inorganic salt with water, etc.

Examples of the water-soluble inorganic salt may include sodium chloride, potassium chloride, etc., but are not limited thereto.

The wetting agent serves as a medium through which the pigment and the water-soluble inorganic salt are uniformly mixed and the pigment can easily be pulverized, and examples of the wetting agent may include alkylene glycol monoalkyl ethers (e.g., ethylene glycol monoethyl ether, propylene glycol monomethyl ether, diethylene glycol monomethyl ether, etc.); and alcohols (e.g., ethanol, isopropanol, butanol, hexanol, cyclohexanol, ethylene glycol, diethylene glycol, polyethylene glycol, glycerin polyethylene glycol, etc.), and these may be used alone or in combination of two or more.

The pigment that has undergone the kneading step may have an average particle diameter of 20 nm to 110 nm. When the average particle diameter of the pigment is within the above range, it is possible to effectively form a fine pattern while having excellent heat resistance and light resistance.

Meanwhile, as specific examples of the dye, C.I. Solvent dyes may include yellow dyes (e.g., C.I. Solvent Yellow 4, 14, 15, 16, 21, 23, 24, 38, 56, 62, 63, 68, 79, 82, 93, 94, 98, 99, 151, 162, 163, etc.); red dyes (e.g., C.I. Solvent Red 8, 45, 49, 89, 111, 122, 125, 130, 132, 146, 179, etc.); orange dyes (e.g., C.I. Solvent Orange 2, 7, 11, 15, 26, 41, 45, 56, 62, etc.); blue dyes (e.g., C.I. Solvent Blue 5, 35, 36, 37, 44, 59, 67, 70, etc.); violet dyes (e.g., C.I. Solvent Violet 8, 9, 13, 14, 36, 37, 47, 49, etc.); green dyes (e.g., C.I. Solvent Green 1, 3, 4, 5, 7, 28, 29, 32, 33, 34, 35, etc.); etc.

Among them, among the C.I. solvent dyes, C.I. Solvent Yellow 14, 16, 21, 56, 151, 79, and 93; C.I. Solvent Red 8, 49, 89, 111, 122, 132, 146, and 179; C.I. Solvent Orange 41, 45, and 62; C.I. Solvent Blue 35, 36, 44, 45, and 70; and C.I. Solvent Violet 13, which have excellent solubility in organic solvents, are preferable. In particular, C.I. Solvent Yellow 21 and 79; C.I. Solvent Red 8, 122, and 132; and C.I. Solvent orange 45 and 62 are more preferable.

Additionally, examples of acid dyes include yellow dyes (e.g., C.I. Acid Yellow 1, 3, 7, 9, 11, 17, 23, 25, 29, 34, 36, 38, 40, 42, 54, 65, 72, 73, 76, 79, 98, 99, 111, 112, 113, 114, 116, 119, 123, 128, 134, 135, 138, 139, 140, 144, 150, 155, 157, 160, 161, 163, 168, 169, 172, 177, 178, 179, 184, 190, 193, 196, 197, 199, 202, 203, 204, 205, 207, 212, 214, 220, 221, 228, 230, 232, 235, 238, 240, 242, 243, 251, etc.); red dyes (e.g., C.I. Acid Red 1, 4, 8, 14, 17, 18, 26, 27, 29, 31, 34, 35, 37, 42, 44, 50, 51, 52, 57, 66, 73, 80, 87, 88, 91, 92, 94, 97, 103, 111, 114, 129, 133, 134, 138, 143, 145, 150, 151, 158, 176, 182, 183, 198, 206, 211, 215, 216, 217, 227, 228, 249, 252, 257, 258, 260, 261, 266, 268, 270, 274, 277, 280, 281, 195, 308, 312, 315, 316, 339, 341, 345, 346, 349, 382, 383, 394, 401, 412, 417, 418, 422, 426, etc.); orange dyes (e.g., C.I. Acid Orange 6, 7, 8, 10, 12, 26, 50, 51, 52, 56, 62, 63, 64, 74, 75, 94, 95, 107, 108, 169, 173, etc.); blue dyes (e.g., C.I. Acid Blue 1, 7, 9, 15, 18, 23, 25, 27, 29, 40, 42, 45, 51, 62, 74, 80, 83, 86, 87, 90, 92, 96, 103, 112, 113, 120, 129, 138, 147, 150, 158, 171, 182, 192, 210, 242, 243, 256, 259, 267, 278, 280, 285, 290, 296, 315, 324:1, 335, 340, etc.); violet dyes (e.g., C.I. Acid Violet 6B, 7, 9, 17, 19, 66, etc.); green dyes (e.g., C.I. Acid Green 1, 3, 5, 9, 16, 25, 27, 50, 58, 63, 65, 80, 104, 105, 106, 109, etc.), etc.

Among the acid dyes above, C.I. Acid Yellow 42; C.I. Acid Red 92; C.I. Acid Blue 80 and 90; C.I. Acid Violet 66; and C.I. Acid Green 27, which have excellent solubility in organic solvents among the acid dyes, are preferable.

Additionally, C.I. direct dyes may include yellow dyes (e.g., C.I. Direct Yellow 2, 33, 34, 35, 38, 39, 43, 47, 50, 54, 58, 68, 69, 70, 71, 86, 93, 94, 95, 98, 102, 108, 109, 129, 136, 138, 141, etc.); red dyes (e.g., C.I. Direct Red 79, 82, 83, 84, 91, 92, 96, 97, 98, 99, 105, 106, 107, 172, 173, 176, 177, 179, 181, 182, 184, 204, 207, 211, 213, 218, 220, 221, 222, 232, 233, 234, 241, 243, 246, 250, etc.); orange dyes (e.g., C.I. Direct Orange 34, 39, 41, 46, 50, 52, 56, 57, 61, 64, 65, 68, 70, 96, 97, 106, 107, etc.); blue dyes (e.g., C.I. Direct Blue 38, 44, 57, 70, 77, 80, 81, 84, 85, 86, 90, 93, 94, 95, 97, 98, 99, 100, 101, 106, 107, 108, 109, 113, 114, 115, 117, 119, 137, 149, 150, 153, 155, 156, 158, 159, 160, 161, 162, 163, 164, 166, 167, 170, 171, 172, 173, 188, 189, 190, 192, 193, 194, 196, 198, 199, 200, 207, 209, 210, 212, 213, 214, 222, 228, 229, 237, 238, 242, 243, 244, 245, 247, 248, 250, 251, 252, 256, 257, 259, 260, 268, 274, 275, 293, etc.); violet dyes (e.g., C.I. Direct Violet 47, 52, 54, 59, 60, 65, 66, 79, 80, 81, 82, 84, 89, 90, 93, 95, 96, 103, 104, etc.); green dyes (e.g., C.I. Direct Green 25, 27, 31, 32, 34, 37, 63, 65, 66, 67, 68, 69, 72, 77, 79, 82, etc.), etc.

Additionally, C.I. modanto dyes may include yellow dyes (e.g., C.I. Modanto Yellow 5, 8, 10, 16, 20, 26, 30, 31, 33, 42, 43, 45, 56, 61, 62, 65, etc.); red dyes (e.g., C.I. Modanto Red 1, 2, 3, 4, 9, 11, 12, 14, 17, 18, 19, 22, 23, 24, 25, 26, 30, 32, 33, 36, 37, 38, 39, 41, 43, 45, 46, 48, 53, 56, 63, 71, 74, 85, 86, 88, 90, 94, 95, etc.); orange dyes (e.g., C.I. Modanto Orange 3, 4, 5, 8, 12, 13, 14, 20, 21, 23, 24, 28, 29, 32, 34, 35, 36, 37, 42, 43, 47, 48, etc.); blue dyes (e.g., C.I. Modanto Blue 1, 2, 3, 7, 8, 9, 12, 13, 15, 16, 19, 20, 21, 22, 23, 24, 26, 30, 31, 32, 39, 40, 41, 43, 44, 48, 49, 53, 61, 74, 77, 83, 84, etc.); violet dyes (e.g., C.I. Modanto Violet 1, 2, 4, 5, 7, 14, 22, 24, 30, 31, 32, 37, 40, 41, 44, 45, 47, 48, 53, 58, etc.); green dyes (e.g., C.I. Modanto Green 1, 3, 4, 5, 10, 15, 19, 26, 29, 33, 34, 35, 41, 43, 53, etc.), etc.

In the present disclosure, each of the dyes may be used alone or in combination of two or more.

The pigment and the dye may be included in an amount of 5 wt % to 40 wt %, more specifically 8 wt % to 30 wt %, based on the total amount of the photosensitive resin composition. When the pigment is included within the above range, it has an absorbance of 0.5/μm or more at a wavelength of 550 nm, and has excellent curability and adhesion of the pattern.

(5) Solvent

As the solvent, materials which have compatibility with the binder resin, the reactive unsaturated compound, the pigment, and the initiator but not reacting may be used.

Examples of the solvent include alcohols (e.g., methanol, ethanol, etc.); ethers (e.g., dichloroethyl ether, n-butyl ether, diisoamyl ether, methylphenyl ether, tetrahydrofuran, etc.); glycol ethers (e.g., ethylene glycol monomethyl ether, ethylene glycol monoethyl ether, etc.); cellosolve acetates (e.g., methyl cellosolve acetate, ethyl cellosolve acetate, diethyl cellosolve acetate, etc.); carbitols (e.g., methylethyl carbitol, diethyl carbitol, diethylene glycol monomethyl ether, diethylene glycol monoethyl ether, diethylene glycol dimethyl ether, diethylene glycol methyl ethyl ether, diethylene glycol diethyl ether, etc.); propylene glycol alkyl ether acetates (e.g., propylene glycol methyl ether acetate, propylene glycol propyl ether acetate, etc.); aromatic hydrocarbons (e.g., toluene, xylene, etc.); ketones (e.g., methyl ethyl ketone, cyclohexanone, 4-hydroxy-4-methyl-2-pentanone, methyl-n-propyl ketone, methyl-n-butyl ketone, methyl-n-amyl ketone, 2-heptanone, etc.); saturated aliphatic monocarboxylic acid alkyl esters (e.g., ethyl acetate, n-butyl acetate, isobutyl acetate, etc.); lactic acid esters such as methyl lactate and ethyl lactate; oxyacetic acid alkyl esters (e.g., methyloxyacetate, ethyloxyacetate, butyl oxyacetate, etc.); alkoxy acetate alkyl esters (e.g., methoxy methyl acetate, methoxy ethyl acetate, methoxy butyl acetate, ethoxy methyl acetate, ethoxy ethyl acetate, etc.); 3-oxypropionic acid alkyl esters (e.g., 3-oxy methyl propionate, 3-oxy ethyl propionate, etc.); 3-alkoxy propionic acid alkyl esters (e.g., 3-methoxy methyl propionate, 3-methoxy ethyl propionate, 3-ethoxy ethyl propionate, 3-ethoxy methyl propionate, etc.); 2-oxypropionic acid alkyl esters (e.g., methyl 2-oxypropionate, ethyl 2-oxypropionate, propyl 2-oxypropionate, etc.); 2-alkoxy propionic acid alkyl esters (e.g., 2-methoxy methyl propionate, 2-methoxy ethyl propionate, 2-ethoxy ethyl propionate, 2-ethoxy methyl propionate, etc.); 2-oxy-2-methyl propionic acid esters (e.g., 2-oxy-2-methyl methyl propionate, 2-oxy-2-methyl ethyl propionate, etc.); monooxy monocarboxylic acid alkyl esters of 2-alkoxy-2-methyl propionic acid alkyls (e.g., 2-methoxy-2-methyl methyl propionate, 2-ethoxy-2-methyl ethyl propionate, etc.); esters (e.g., 2-hydroxyethyl propionate, 2-hydroxy-2-methyl ethyl propionate, ethyl hydroxyacetate, 2-hydroxy-3-methyl methyl butanoate, etc.); ketonic acid esters (e.g., ethyl pyruvate, etc.), etc.

Further, high boiling point solvents such as N-methylformamide, N,N-dimethylformamide, N-methylformanilad, N-methylacetamide, N,N-dimethylacetamide, N-methylpyrrolidone, dimethyl sulfoxide, benzylethyl ether, dihexyl ether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, and phenyl cellosolve acetate may also be used.

Among the solvents, in consideration of compatibility and reactivity, glycol ethers (e.g., ethylene glycol monoethyl ether, etc.); ethylene glycol alkyl ether acetates (e.g., ethyl cellosolve acetate, etc.); esters (e.g., ethyl 2-hydroxypropionate, etc.); carbitols (e.g., diethylene glycol monomethyl ether, etc.); and propylene glycol alkyl ether acetates (e.g., propylene glycol methyl ether acetate, propylene glycol propyl ether acetate, etc.) may be used.

The solvent may be included as a balance based on the total amount of the photosensitive resin composition, and specifically may be included in an amount of 50 to 90 wt %. When the solvent is included within the above range, the photosensitive resin composition has an appropriate viscosity, and thus the processability is excellent in preparing the pattern layer.

In addition, another embodiment of the present disclosure can provide a display device.

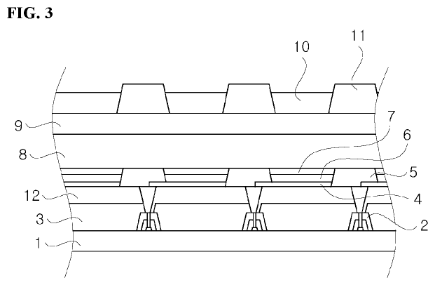

Hereinafter, a display device will be described with reference to FIG. 3. The display device according to an exemplary embodiment of the present disclosure is a display device which includes a first electrode (4) formed on a substrate (1) and a second electrode (7) installed to face the first electrode, and a pattern or film formed of the photosensitive resin composition according to the present disclosure, in which the pattern or film is formed of a photosensitive resin that contains a polymer having the structural unit represented by Formula (1) above as an active ingredient.

In the display device according to the embodiments of the present disclosure, the photosensitive resin composition is the same as the photosensitive resin composition according to the above-described embodiments of the present disclosure and is thus omitted.

The display device may include an organic light emitting device and a color filter, and the color filter may be formed on the organic light emitting device using the photosensitive composition of the present disclosure.

The organic light emitting device may be divided into a red organic light emitting device, a green organic light emitting device, a blue organic light emitting device, an orange organic light emitting device, a white organic light emitting device, etc. by the pixel separation unit (5). In the organic light emitting device, a first electrode, an organic layer (6), and a second electrode may be sequentially stacked, and a sealing layer (8) including organic and inorganic materials may be formed on the second electrode to be blocked from moisture and oxygen.

The color filter may be positioned on an upper part of the sealing layer and may include a color unit (10) aligned in a vertical direction with reference to the organic light emitting device and a color separation unit (11) that separates the color unit.

The photosensitive composition of the present disclosure may be included in the color unit or the color separation unit and narrows the wavelength range of light emitted from the organic light emitting device thereby improving color purity and blocks light incident from the outside of the organic light emitting device thereby improving outdoor visibility.

The photosensitive composition of the present disclosure may include a red pigment or red dye to form a red color unit vertically aligned with the red organic light emitting diode.

The photosensitive composition of the present disclosure may include a green pigment or green dye to form a green color unit vertically aligned with the green organic light emitting diode.

The photosensitive composition of the present disclosure may include a blueish pigment or blue dye to form a blue color unit vertically aligned with the blue organic light emitting diode.

The photosensitive composition of the present disclosure may include a black pigment or black dye to form a color separation unit vertically aligned with the pixel separation unit.

When the color unit or color separation unit of the color filter is formed using the photosensitive composition of the present disclosure, it has a low outgassing amount and may form a pattern of a fine size, and thus a high resolution color filter can be prepared.

The display device may include a TFT layer (3), which includes a thin film transistor (TFT (2)), between the substrate (1) and the first electrode (4) and may include a flattening layer (12) on the TFT layer. In addition, the display device may include several functional layers such as a touch screen panel (TSP: (9)) layer between the sealing layer (8) and the color filter so as to manipulate the display device by way of touching.

The photosensitive composition of the present disclosure may be patterned on the TSP layer to form a color filter. The composition of the present disclosure may be patterned on the TSP layer to form a color unit or color separation unit and may be included in both the color unit and the color separation unit simultaneously.

Hereinafter, Synthesis Examples and Examples according to the present disclosure will be specifically described, but these Synthesis Examples and Examples of the present disclosure are not limited thereto.

### Synthesis Example 1

### Preparation of Compound 1-1

20 g of 9,9′-bisphenol fluorene (Sigma Aldrich), 8.67 g of glycidyl chloride (Sigma Aldrich), 30 g of anhydrous potassium carbonate, and 100 mL of dimethylformamide were added into a 300 mL 3-neck round-bottom flask equipped with a distillation tube, and the temperature was raised to 80° C. and reacted for 4 hours. Then, the temperature was lowered to 25° C. and the reaction solution was filtered and the filtrate was added dropwise to 1,000 mL of water while stirring, and the precipitated powder was filtered and dried under reduced pressure at 40° C. to obtain Compound 1-1 (25 g). The obtained powder was subjected to purity analysis by HPLC and was shown to have a purity of 98%.

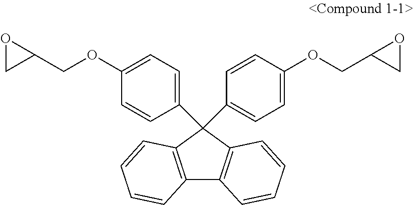 [SMILES: c1ccc2c(c1)-c1ccccc1C2(c1ccc(OCC2CO2)cc1)c1ccc(OCC2CO2)cc1]

### Synthesis Example 2

### Preparation of Compounds 2-1 to 2-3

25 g (54 mmol) of Compound 1-1 obtained in Synthesis Example 1, 8 g of acrylic acid (Daejung Chemicals & Metals), 0.2 g of benzyltriethylammonium chloride (Daejung Chemicals & Metals), 0.2 g of hydroquinone (Daejung Chemicals & Metals), and 52 g of toluene (Sigma Aldrich) were added into a 300 mL 3-neck round-bottom flask equipped with a distillation tube and the mixture was stirred at 110° C. for 6 hours. After completion of the reaction, toluene was removed by distillation under reduced pressure to obtain a product. After a glass column with a diameter of 220 mm was filled with 500 g of silica gel 60 (230-400 mesh, Merck), 20 g of the product was added thereinto, and separation was performed using 10 L of a solvent in which hexane and ethyl acetate were mixed in a 4:1 volume ratio to isolate Compounds 2-1 to 2-3.

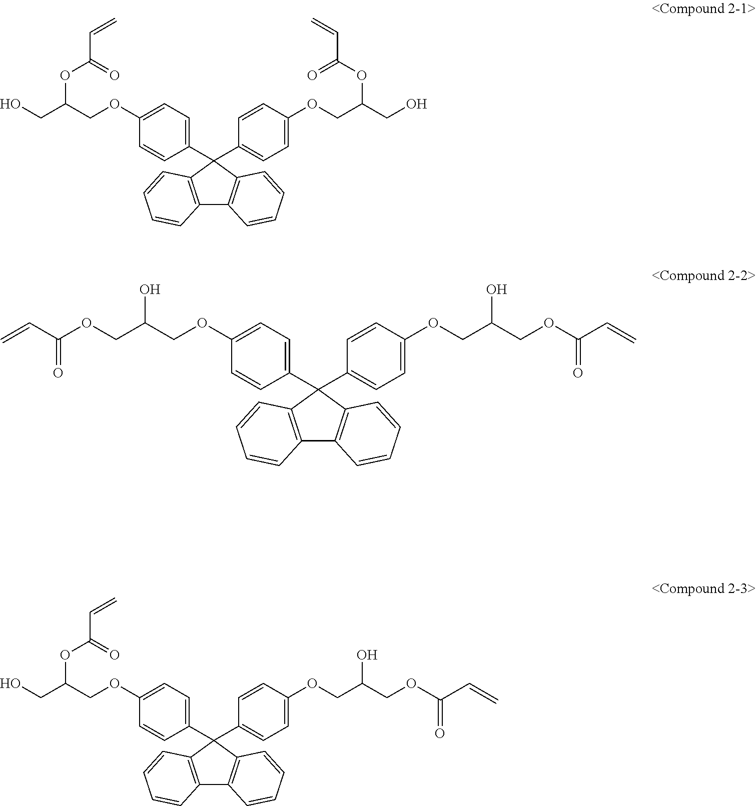 [SMILES: C=CC(=O)OC(CO)COc1ccc(C2(c3ccc(OCC(CO)OC(=O)C=C)cc3)c3ccccc3-c3ccccc32)cc1 ; C=CC(=O)OCC(O)COc1ccc(C2(c3ccc(OCC(O)COC(=O)C=C)cc3)c3ccccc3-c3ccccc32)cc1 ; C=CC(=O)OCC(O)COc1ccc(C2(c3ccc(OCC(CO)OC(=O)C=C)cc3)c3ccccc3-c3ccccc32)cc1]

### Synthesis Examples 3 TO 9

### Preparation of Polymers 1-1 to 1-7

Compound 2-1, Compound 2-2, and Compound 2-3 obtained in Synthesis Example 2 were each added into a 50 mL 3-neck round-bottom flask equipped with a distillation tube, respectively, as shown in Table 1 below, and 0.1 g of tetraethylammonium bromide (Daejung Chemicals & Metals), 0.03 g of hydroquinone (Daejung Chemicals & Metals), and 8.05 g of propylene glycol methyl ether acetate (Sigma Aldrich) were added into a 50 mL 3-neck round-bottom flask equipped with a distillation tube, and 1.22 g of biphenyltetracarboxylic dianhydride (Mitsubishi Gas) and 0.38 g of tetrahydrophthalic acid (Sigma Aldrich Co.) were additionally added thereto and the mixture was stirred at 110° C. for 6 hours. After completion of the reaction, the reaction solution was recovered to obtain Polymers 1-1 to 1-7 containing repeating units such as Compounds 2-1, 2-2, and 2-3 in the form of a solution containing 45% solids. The synthesized polymers were analyzed for weight average molecular weight (Mw) using gel permeation chromatography (Agilent).

TABLE 1

| | Synthesis | Synthesis | Synthesis | Synthesis | Synthesis | Synthesis | Synthesis |
|---|---|---|---|---|---|---|---|
| | Example 3 | Example 4 | Example 5 | Example 6 | Example 7 | Example 8 | Example 9 |
| | (Polymer 1-1) | (Polymer 1-2) | (Polymer 1-3) | (Polymer 1-4) | (Polymer 1-5) | (Polymer 1-6) | (Polymer 1-7) |
| Compound | 3 g | 1 g | 1 g | 4.25 g | 0.25 g | 5 g | 0 g |
| 2-1 | | | | | | | |
| Compound | 1 g | 3 g | 1 g | 0.25 g | 4.25 g | 0 g | 5 g |
| 2-2 | | | | | | | |
| Compound | 1 g | 1 g | 3 g | 0.5 g | 0.5 g | 0 g | 0 g |
| 2-3 | | | | | | | |
| Weight | 4,800 | 4,200 | 4,600 | 4,400 | 4,100 | 5,200 | 3,300 |
| Average | g/mol | g/mol | g/mol | g/mol | g/mol | g/mol | g/mol |
| Molecular | | | | | | | |
| Weight | | | | | | | |

### Synthesis Example 10

### Preparation of Compound 3-1

20 g (0.147 mol) of trichloro silane (Gelest) and 17.51 g (0.147 mol) of 6-chloro-1-hexene (Aldrich) were dissolved in 200 mL of ethyl acetate in a 3-neck round-bottom flask equipped with a distillation tube to which cooling water was connected, and then 0.02 g of a platinum(0)-1,3-divinyl-1,1,3,3-tetramethyldisiloxane complex solution (2 wt % in xylene/Aldrich) was added, and the temperature was raised to 75° C. while adding nitrogen thereto and the mixture was allowed to react for 5 hours, and the solution was filtered with a 0.1 μm Teflon membrane to remove the platinum catalyst. Thereafter, 15.6 g (0.487 mol) of methanol was added dropwise at room temperature for 30 minutes, and the temperature was again raised to and the mixture was allowed to react for additional 2 hours, and the reaction solution was distilled under reduced pressure to remove the solvent. 24 g (0.1 mol) of the thus-obtained 6-chlorohexyltrimethoxysilane, 8 g (0.15 mol) of sodium methoxide (Aldrich), and 187 mL (0.15 mol) of a hydrogen sulfide THF solution (0.8 M concentration), and 100 mL of methanol were added into an autoclave, and the mixture was allowed to react at 100° C. for 2 hours. After cooling the reaction solution, 100 mL of hydrogen chloride in methanol (1.25 M concentration) was added thereto dropwise at room temperature for 30 minutes, the resulting salt was filtered off, and then distilled under reduced pressure to obtain Compound 3-1 (23 g).

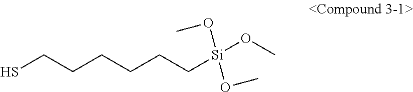

### Synthesis Example 11

### Preparation of Compound 3-2

Compound 3-2 (24 g) was obtained by synthesis in the same manner as in Synthesis Example 10 above, except that 23.7 g (0.147 mol) of 9-chloro-1-nonene (AK Scientific) was used instead of 6-chloro-1-hexene in Synthesis Example 10.

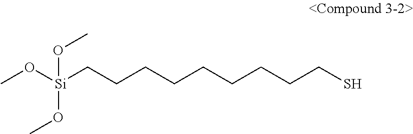 [SMILES: CO[Si](CCCCCCCCCS)(OC)OC]

### Synthesis Example 12

### Preparation of Compound 3-3

Compound 3-3 (26 g) was obtained by synthesis in the same manner as in Synthesis Example 10, except that 30 g (0.147 mol) of 12-chloro-1-dodecene (Atomax Chemicals) was used instead of 6-chloro-1-hexene in Synthesis Example 10.

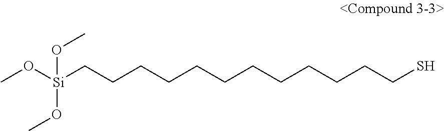 [SMILES: CO[Si](CCCCCCCCCCCCS)(OC)OC]

### Synthesis Example 13

### Preparation of Compound 3-4

Compound 3-4 (24 g) was obtained by synthesis in the same manner as in Synthesis Example 10, except that 22.4 g (0.487 mol) of ethanol (Aldrich) was used instead of methanol which was added after removing platinum in Synthesis Example 10.

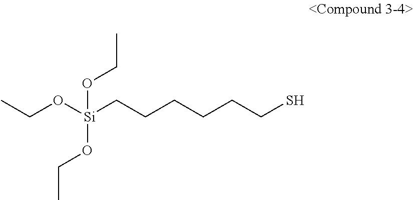 [SMILES: CCO[Si](CCCCCCS)(OCC)OCC]

### Synthesis Example 14

### Preparation of Compound 3-5

Compound 3-5 (27 g) was obtained by synthesis in the same manner as in Synthesis Example 10, except that 36 g (0.487 mol) of 1-butanol (Aldrich) was used instead of methanol added after removing platinum in Synthesis Example 10.

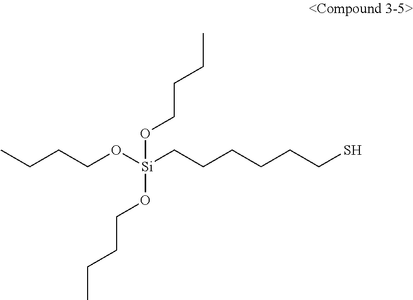 [SMILES: CCCCO[Si](CCCCCCS)(OCCCC)OCCCC]

### Synthesis Example 15

### Preparation of Compound 3-6

Compound 3-6 (22 g) was obtained by synthesis in the same manner as in Synthesis Example 10, except that 18 g (0.147 mol) of dichloromethylsilane was used instead of trichlorosilane in Synthesis Example 10.

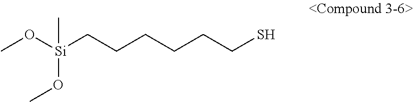

### Synthesis Example 16

### Preparation of Polymer 2-1

6.36 g (34 mmol) of KBM 803 [3-(trimethoxysilyl)-1-propanethiol] (Shinetsu), which is the same as Compound 3-7, was added to 360 g of the solution of Polymer 1-1 prepared in Synthesis Example 3, and the temperature was raised to 60° C. and the mixture was stirred for 4 hours to obtain Polymer 2-1, which is a cardo-based binder resin the same as Compound 3-7 where a silane group is substituted.

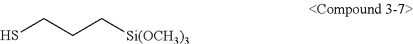

### Synthesis Examples 17 TO 22

### Preparation of Polymers 2-2 to 2-7

Polymers 2-2 to 2-7, which are cardo-based binder resins where a silane group is substituted, were prepared in the same manner as in Synthesis Example 16, except that Polymers 1-2 to 1-7 described in Table 2 were used instead of the solution of Polymer 1-1 in Synthesis Example 16.

The weight average molecular weights of Polymers 2-1 to 2-7 synthesized in Synthesis Examples 16 to 22 are shown in Table 2 below.

TABLE 2

| | Synthesis | Synthesis | Synthesis | Synthesis | Synthesis | Synthesis | Synthesis |
|---|---|---|---|---|---|---|---|
| | Example | Example | Example | Example | Example | Example | Example |
| | 16 | 17 | 18 | 19 | 20 | 21 | 22 |
| | (Polymer | (Polymer | (Polymer | (Polymer | (Polymer | (Polymer | (Polymer |
| | 2-1) | 2-2) | 2-3) | 2-4) | 2-5) | 2-6) | 2-7) |
| Polymer | Polymer | Polymer | Polymer | Polymer | Polymer | Polymer | Polymer |
| backbone | 1-1 | 1-2 | 1-3 | 1-4 | 1-5 | 1-6 | 1-7 |
| Silane | Compound | Compound | Compound | Compound | Compound | Compound | Compound |
| Group | 3-7 | 3-7 | 3-7 | 3-7 | 3-7 | 3-7 | 3-7 |
| Weight | 4,880 | 4,250 | 4,680 | 4,430 | 4,140 | 5,270 | 3,320 |
| Average | g/mol | g/mol | g/mol | g/mol | g/mol | g/mol | g/mol |
| Molecular | | | | | | | |
| Weight | | | | | | | |

### Synthesis Example 23

### Preparation of Polymer 3-1

8.1 g (34 mmol) of 6-(trimethoxysilyl)-1-hexanethiol (Compound 3-1) was added to 360 g of the solution of Polymer 1-1 prepared in Synthesis Example 3, and the temperature was raised to 60° C., and the mixture was stirred for 4 hours to obtain Polymer 3-1, which is a cardo-based binder resin the same as Compound 3-1 where a silane group is substituted.

### Synthesis Examples 24 TO 29

### Preparation of Polymers 3-2 to 3-7

Polymer 3-2 to Polymer 3-7, which are cardo-based binder resins where a silane group is substituted, were prepared in the same manner as in Synthesis Example 23, except that Polymers 1-2 to 1-7 described in Table 3 were used instead of the solution of Polymer 1-1 in Synthesis Example 23.

The weight average molecular weights of Polymers 3-1 to 3-7 synthesized in Synthesis Examples 23 to 29 are shown in Table 3 below.

TABLE 3

| | Synthesis | Synthesis | Synthesis | Synthesis | Synthesis | Synthesis | Synthesis |
|---|---|---|---|---|---|---|---|
| | Example | Example | Example | Example | Example | Example | Example |
| | 23 | 24 | 25 | 26 | 27 | 28 | 29 |
| | (Polymer | (Polymer | (Polymer | (Polymer | (Polymer | (Polymer | (Polymer |
| | 3-1) | 3-2) | 3-3) | 3-4) | 3-5) | 3-6) | 3-7) |
| Polymer | Polymer | Polymer | Polymer | Polymer | Polymer | Polymer | Polymer |
| backbone | 1-1 | 1-2 | 1-3 | 1-4 | 1-5 | 1-6 | 1-7 |
| Silane | Compound | Compound | Compound | Compound | Compound | Compound | Compound |
| Group | 3-1 | 3-1 | 3-1 | 3-1 | 3-1 | 3-1 | 3-1 |
| Weight | 4,900 | 4,280 | 4,690 | 4,470 | 4,160 | 5,290 | 3,360 |
| Average | g/mol | g/mol | g/mol | g/mol | g/mol | g/mol | g/mol |
| Molecular | | | | | | | |
| Weight | | | | | | | |

### Synthesis Example 30

### Preparation of Polymer 4-1

9.53 g (34 mmol) of 6-(triethoxysilyl)-1-hexanethiol (Compound 3-4) was added to 360 g of the solution of Polymer 1-1 prepared in Synthesis Example 3, and the temperature was raised to 60° C., and the mixture was stirred for 4 hours to obtain Polymer 4-1, which is a cardo-based binder resin the same as Compound 3-4 where a silane group is substituted.

### Synthesis Examples 31 TO 36

### Preparation of Polymers 4-2 to 4-7

Polymers 4-2 to Polymer 4-7, which are cardo-based binder resins where a silane group is substituted, were prepared in the same manner as in Synthesis Example 30, except that Polymers 1-2 to 1-7 described in Table 4 were used instead of the solution of Polymer 1-1 in Synthesis Example 30.

The weight average molecular weights of Polymer 4-1 to 4-7 synthesized in Synthesis Examples 30 to 36 are shown in Table 4 below.

TABLE 4

| | Synthesis | Synthesis | Synthesis | Synthesis | Synthesis | Synthesis | Synthesis |
|---|---|---|---|---|---|---|---|
| | Example | Example | Example | Example | Example | Example | Example |
| | 30 | 31 | 32 | 33 | 34 | 35 | 36 |
| | (Polymer | (Polymer | (Polymer | (Polymer | (Polymer | (Polymer | (Polymer |
| | 4-1) | 4-2) | 4-3) | 4-4) | 4-5) | 4-6) | 4-7) |
| Polymer | Polymer | Polymer | Polymer | Polymer | Polymer | Polymer | Polymer |
| backbone | 1-1 | 1-2 | 1-3 | 1-4 | 1-5 | 1-6 | 1-7 |
| Silane | Compound | Compound | Compound | Compound | Compound | Compound | Compound |
| Group | 3-4 | 3-4 | 3-4 | 3-4 | 3-4 | 3-4 | 3-4 |
| Weight | 4,900 | 4,290 | 4,690 | 4,480 | 4,180 | 5,290 | 3,380 |
| Average | g/mol | g/mol | g/mol | g/mol | g/mol | g/mol | g/mol |
| Molecular | | | | | | | |
| Weight | | | | | | | |

### Synthesis Example 37

### Preparation of Compound 4-1

20 g of pentaerythritol (Sigma Aldrich) and 42.77 g of acrylic acid (Sigma Aldrich) were added together with 100 g of toluene into a 300 mL 3-neck round-bottom flask equipped with a distillation tube and a Dean-Stark tube, and 1 g of sulfuric acid was added thereto, and the temperature was raised to 110° C. and the mixture was allowed to react for 8 hours. Then, the temperature was lowered to 25° C. and the reaction solution was washed 3 times with 200 mL of an aqueous solution of 10 wt % Na₂CO₃, washed once with 200 mL of water, and then the supernatant organic solution was dried at 40° C. under reduced pressure to obtain Compound 4-1 (50 g).

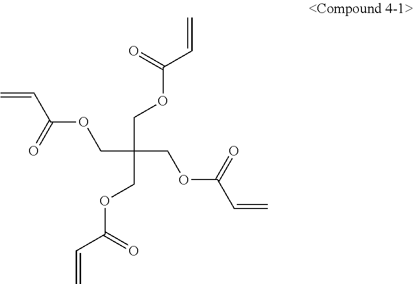 [SMILES: C=CC(=O)OCC(COC(=O)C=C)(COC(=O)C=C)COC(=O)C=C]

### Synthesis Example 38

### Preparation of Compound 5-1

10 g of 1-methoxynaphthalene (TCI) and 12.7 g of 3-oxo-3-phenylpropanoyl chloride were added into a 300 mL 3-necked round-bottom flask in an N₂ atmosphere together with 120 mL of dichloro ethane, and the mixture was dissolved by stirring and then cooled to 5° C. After adding 9.27 g of aluminum chloride (Aldrich) thereto little by little for 30 minutes, the mixture was stirred for 1 hour, and after raising the temperature to room temperature, and the mixture was stirred for 2 hours. After adding 100 mL of a 1 N HCl aqueous solution to the reaction solution and stirring, the organic layer was collected, washed 3 times with 100 mL of distilled water, distilled under reduced pressure, and separated using a silica gel column to obtain 13.4 g of Compound 5-1.

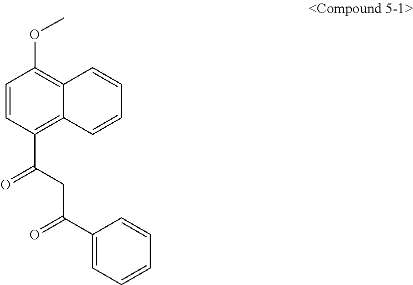 [SMILES: COc1ccc(C(=O)CC(=O)c2ccccc2)c2ccccc12]

### Synthesis Example 39

### Preparation of Compound 5-2

10 g of Compound 5-1 obtained in Synthesis Example 38 and 27.8 g of 1V, N-dimethylformamide (Aldrich) were added into a 100 mL 3-necked round-bottom flask in N₂ atmosphere and dissolved, cooled to 5° C., and then, 35 wt % (5.5 g) of an aqueous solution of HCl and 8 g of isobutyl acetate (Aldrich) were added dropwise to the reactor for 30 minutes and the mixture was allowed to react for 10 hours. After the reaction, the resultant was washed with 100 mL of distilled water 5 times, distilled under reduced pressure, and separated using a silica gel column to obtain 5.48 g of Compound 5-2.

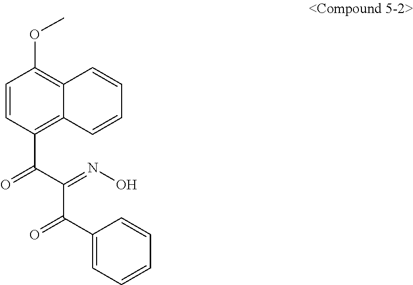 [SMILES: COc1ccc(C(=O)/C(=N/O)C(=O)c2ccccc2)c2ccccc12]

### Synthesis Example 40

### Preparation of Compound 5-3

5 g of Compound 5-2 obtained in Synthesis Example 39 and 1.4 g of acetyl chloride were dissolved by adding together with 50 mL of dichloroethane into a 100 mL 3-necked round-bottom flask in N₂ atmosphere, and then cooled to 5° C., and then 1.8 g of triethyl amine was added thereto dropwise for 30 minutes. Then, the temperature was raised to room temperature and the mixture was stirred for 2 hours. After washing 3 times with 100 mL of distilled water, the resultant was distilled under reduced pressure and separated using a silica gel column to obtain 4.5 g of Compound 5-3.

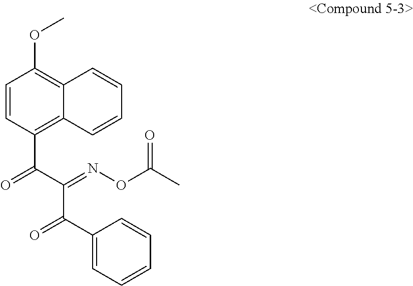 [SMILES: COc1ccc(C(=O)/C(=N/OC(C)=O)C(=O)c2ccccc2)c2ccccc12]

### Preparation Example 1

### Preparation of red pigment dispersion

15 g of Irgaphor Red BT-CF (red pigment/BASF), 8.5 g of Disperbyk 163 (BYK), 6.5 g of the polymer solution obtained in Synthesis Examples 3 to 9 and Synthesis Examples 16 to 22, 70 g of propylene glycol methyl ether acetate, and 100 g of zirconia beads with a diameter of 0.5 mm (Toray) were dispersed using a paint shaker (Asada) for 10 hours to obtain a dispersion.

### Experimental Example 1

### Measurement of Molar Absorption Coefficient and Temperature of 5% Weight Loss of Photoinitiator Compound

The maximum molar absorption coefficients of Compound 5-3 prepared in Synthesis Example 40, OXE-02 (BASF), and 1-hydroxycyclohexyl phenyl ketone were measured in the region of 320 nm to 380 nm using a UV-Vis spectrometer UV-2600 (Shimadzu) was measured, and the temperatures at which a 5% weight loss occurs in the three compounds were measured using TGA Q50 (TA), and the measured values are shown in Table

TABLE 5

| | Temperature of | Maximum Molar Absorption |
|---|---|---|
| | 5% Weight Loss | Coefficient in Region of 320 |
| | (° C.) | nm to 380 nm (L/mol · cm) |
| Compound 5-3 | 188.53 | 16,000 (@332 nm) |
| OXE-02 (BASF) | 250.13 | 21,000 (@338 nm) |
| 1-Hydroxycyclohexyl | 143.12 | 2,400 (@330 nm) |
| phenyl ketone | | 14,000 (@245 nm) |

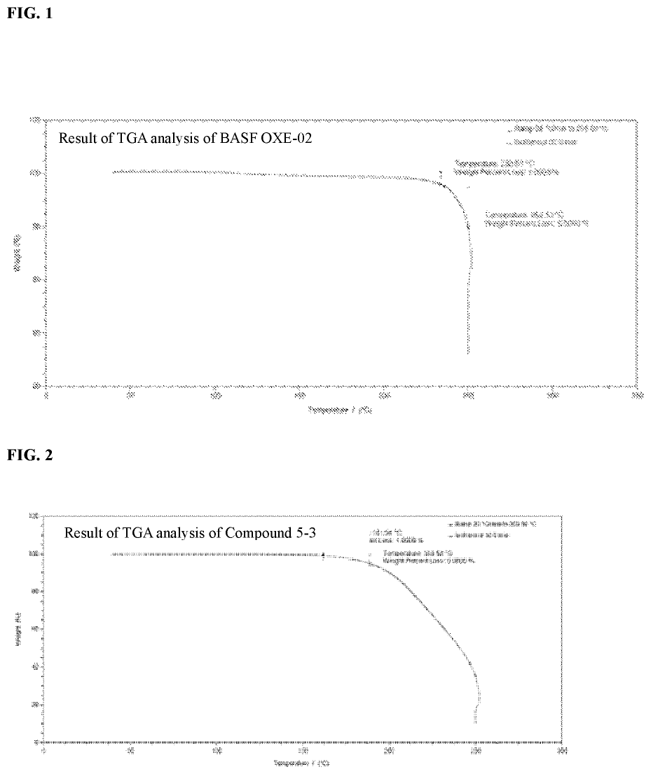

Referring to Table 5 above, in the case of OXE-02, as shown in FIG. 1, the temperature at which the 5% weight loss occurs was 250° C. or higher, indicating a relatively high value compared to that of Compound 5-3, and the maximum molar absorption coefficient in the region of 320 nm to 380 nm was measured to be 21,000 (L/mol·cm) in the wavelength region of 338 nm.

Meanwhile, in the case of 1-hydroxycyclohexyl phenyl ketone, the maximum molar absorption coefficient in the region of 320 nm to 380 nm was very low as low as 2,400 (L/mol·cm) at 330 nm, and a rapid weight loss was shown at a temperature near 140° C.

In contrast, in the case of Compound 5-3 synthesized in Synthesis Example 40, as shown in FIG. 2, the 5% weight loss occurred at 188.53° C., and the maximum molar absorption coefficient in the region of 320 nm to 380 nm was measured to be 16,000 (L/mol·cm) at 332 nm of wavelength.

### Examples 1 to 10

The photosensitive composition solutions were prepared according to the compositions shown in Table 6 below.

TABLE 6

| | Exam- | Exam- | Exam- | Exam- | Exam- | Exam- | Exam- | Exam- | Exam- | Exam- |
|---|---|---|---|---|---|---|---|---|---|---|
| | ple 1 | ple 2 | ple 3 | ple 4 | ple 5 | ple 6 | ple 7 | ple 8 | ple 9 | ple 10 |
| Red Pigment | 30 | 30 | 30 | 30 | 30 | 30 | 30 | 30 | 30 | 30 |
| Dispersion of | | | | | | | | | | |
| Preparation | | | | | | | | | | |
| Example 1 | | | | | | | | | | |
| Compound 4-1 | 7 | 7 | 7 | 7 | 7 | 7 | 7 | 7 | 7 | 7 |
| Compound 5-3 | 0.5 | 0.5 | 0.5 | 0.5 | 0.5 | 0.5 | 0.5 | 0.5 | 0.5 | 0.5 |
| Polymer 1-1 | 7 | — | — | — | — | — | — | — | — | — |
| Polymer 1-2 | — | 7 | — | — | — | — | — | — | — | — |
| Polymer 1-3 | — | — | 7 | — | — | — | — | — | — | — |
| Polymer 1-4 | — | — | — | 7 | — | — | — | — | — | — |
| Polymer 1-5 | — | — | — | — | 7 | — | — | — | — | — |
| Polymer 2-1 | — | — | — | — | — | 7 | — | — | — | — |
| Polymer 2-2 | — | — | — | — | — | — | 7 | — | — | — |
| Polymer 2-3 | — | — | — | — | — | — | — | 7 | — | — |
| Polymer 2-4 | — | — | — | — | — | — | — | — | 7 | — |
| Polymer 2-5 | — | — | — | — | — | — | — | — | — | 7 |
| Propylene Glycol | 55.5 | 55.5 | 55.5 | 55.5 | 55.5 | 55.5 | 55.5 | 55.5 | 55.5 | 55.5 |
| Methyl Ether | | | | | | | | | | |
| Acetate (Daicel) | | | | | | | | | | |

### Comparative Examples 1 to 9

Photosensitive composition solutions were prepared according to the compositions shown in Table 7 below.

TABLE 7

| | Compar- | Compar- | Compar- | Compar- | Compar- | Compar- | Compar- | Compar- | Compar- |
|---|---|---|---|---|---|---|---|---|---|
| | ative | ative | ative | ative | ative | ative | ative | ative | ative |
| | Exam- | Exam- | Exam- | Exam- | Exam- | Exam- | Exam- | Exam- | Exam- |
| | ple 1 | ple 2 | ple 3 | ple 4 | ple 5 | ple 6 | ple 7 | ple 8 | ple 9 |
| Red Pigment | 30 | 30 | 30 | 30 | 30 | 30 | 30 | 30 | 30 |
| Dispersion of | | | | | | | | | |
| Preparation | | | | | | | | | |
| Example 1 | | | | | | | | | |
| Compound 4-1 | 7 | 7 | 7 | 7 | 7 | 7 | 7 | 7 | 7 |
| Compound 5-3 | 0.5 | 0.5 | 0.5 | 0.5 | 0.5 | — | — | — | — |
| OXE-02 (BASF) | — | — | — | — | — | 0.5 | — | 0.5 | — |
| 1- | — | — | — | — | — | — | 0.5 | — | 0.5 |
| Hydroxycyclohexyl | | | | | | | | | |
| Phenyl Ketone | | | | | | | | | |
| Polymer 1-1 | — | — | — | — | — | 7 | 7 | — | — |
| Polymer 2-1 | — | — | — | — | — | — | — | 7 | 7 |
| Polymer 1-6 | 7 | — | — | — | — | — | — | — | — |
| Polymer 1-7 | — | 7 | — | — | — | — | — | — | — |
| Polymer 2-6 | — | — | 7 | — | — | — | — | — | — |
| Polymer 2-7 | — | — | — | 7 | — | — | — | — | — |
| SR-6100 (SMS) | — | — | — | — | 7 | — | — | — | — |
| Propylene Glycol | 55.5 | 55.5 | 55.5 | 55.5 | 55.5 | 55.5 | 55.5 | 55.5 | 55.5 |
| Methyl Ether | | | | | | | | | |
| Acetate (Daicel) | | | | | | | | | |

The preparation method of the light blocking layer using the composition solutions according to Tables 6 and 7 is as follows (a photolithography step).

(1) Step of Coating and Film Formation

The red photosensitive resin composition described above was applied to a washed ITO/Ag substrate (10 cm*10 cm) to a thickness of 1.5 μm using a spin coater, and then heated at a temperature of 100° C. for 1 minute to remove the solvent to thereby form a coating film.

(2) Step of Light Exposure

In order to form a pattern required for the obtained coating film, a mask of a predetermined shape was interposed, and then irradiation was performed with actinic rays of 190 nm to 500 nm. The light exposure machine used was MA-6, and the amount of light exposure was 100 mJ/cm².

(3) Step of Development

Following the step of light exposure, the coating film was developed by dipping it into the AX 300 MIF developer solution (AZEM) at 25° C. for 1 minute, and then it was washed with water to dissolve and remove the unexposed parts, thereby leaving only the exposed parts to form an image pattern.

(4) Step of Post-Processing

In order to obtain an excellent pattern in terms of heat resistance, light resistance, adhesion, crack resistance, chemical resistance, high strength, storage stability, etc., the image pattern obtained by the above development was subjected to post baking in an oven at 230° C. for 30 minutes.

(5) Measurement of Outgas

After forming a coating film on a glass substrate through the steps (1), (2), (3), and (4) above, the photosensitive compositions of Examples 1 to 10 and Comparative Examples 1 to 9 were cut to a size of 1 cm×3 cm and six samples 6 were prepared for each. Outgas was each collected at 250° C. for 30 minutes using JTD-505III of JAI. After measuring toluene assay samples (100 ppm, 500 ppm, and 1,000 ppm) using QP2020 GC/MS (Shimadzu), calibration curves were drawn up, and the amounts of outgas generated by the collected samples were measured.

The amounts of outgas generated of the patterns thus obtained and the maximum resolution (a minimum size pattern on the substrate) of the pattern formed on the substrate were measured, and are shown in Tables 8 and 9.

TABLE 8

| | Exam- | Exam- | Exam- | Exam- | Exam- | Exam- | Exam- | Exam- | Exam- | Exam- |
|---|---|---|---|---|---|---|---|---|---|---|
| | ple 1 | ple 2 | ple 3 | ple 4 | ple 5 | ple 6 | ple 7 | ple 8 | ple 9 | ple 10 |
| Minimum Pattern | 5.2 | 5.4 | 5.5 | 5.6 | 5.6 | 3.6 | 3.8 | 4.0 | 4.2 | 4.3 |
| Size on Substrate | | | | | | | | | | |
| (μm) | | | | | | | | | | |
| Amount Of Outgas | 3.1 | 3.0 | 3.3 | 3.2 | 3.1 | 3.7 | 3.8 | 3.6 | 3.5 | 3.7 |
| Generated (ppm) | | | | | | | | | | |

TABLE 9

| | Compar- | Compar- | Compar- | Compar- | Compar- | Compar- | Compar- | Compar- | Compar- |
|---|---|---|---|---|---|---|---|---|---|
| | ative | ative | ative | ative | ative | ative | ative | ative | ative |
| | Exam- | Exam- | Exam- | Exam- | Exam- | Exam- | Exam- | Exam- | Exam- |
| | ple 1 | ple 2 | ple 3 | ple 4 | ple 5 | ple 6 | ple 7 | ple 8 | ple 9 |
| Minimum Pattern | 7.4 | 7.8 | 6.2 | 6.3 | 12.6 | 5.4 | 14.9 | 4.5 | 13.1 |
| Size on Substrate | | | | | | | | | |
| (μm) | | | | | | | | | |
| Amount Of | 3.4 | 3.1 | 4.1 | 3.9 | 4.8 | 8.9 | 3.2 | 9.2 | 3.7 |
| Outgas Generated | | | | | | | | | |
| (ppm) | | | | | | | | | |

As shown in Table 8, it can be seen that there is a tendency that the amount of outgas generation in Examples 1 to 5, in which Polymers 1-1 to 1-5 not containing a silane substituent were used as a binder resin, is lower than that in Examples 6 to 10, in which Polymers 2-1 to 2-containing a silane substituent were used as a binder resin.

In addition, in the case of Examples 6 to 10, they showed a tendency in which the minimum size pattern on the substrate is smaller compared to Examples 1 to 5. It is speculated that this is because when a binder resin substituted with a silane group is used, the adhesion to the substrate is improved, thereby improving the resolution of the final pattern after the PR process, but it also results in an increase of the amount of outgas generated.

Comparative Examples 1 to 4 of Table 9 also showed a similar tendency to Examples 1 to 10. In the case of Comparative Examples 3 and 4 in which Polymers 2-6 and 2-7 where a silane substituent is substituted were used, the size of the minimum size pattern became smaller thus improving the resolution and the amount of outgas generated was also increased compared to Comparative Examples 1 and 2, in which Polymers 1-6 and 1-7 where a silane substituent is not substituted were used.

When comparing Examples 1 to 10 of Table 8 above and Comparative Examples 1 to 4 of Table 9 above, in the cases of Polymers 1-6, 1-7, 2-6, 2-7, a polymer backbone is formed by polymerizing one type of monomer and has a relatively linear shape compared to Polymers 1-1 to 1-5 and Polymers 2-1 to 2-5 depending on the structure of the monomer.

In contrast, in the case of Polymers 1-1 to 1-5 and Polymers 2-1 to 2-5 used in Examples 1 to 10, the polymer main chain is polymerized with three types of monomers having different structures thus having a relatively reticulated structure compared to Polymers 1-6, 1 1-7, 2-6, and 2-7.

Polymers 1-1 to 1-5 and Polymers 2-1 to 2-5, due to their structural characteristics, can have an effective intermolecular bonding with surrounding compounds thus being more suitable for a photolithography process; accordingly, it is speculated that Examples 1 to 10 show higher resolution than in the developing process is higher than Comparative Examples 1 to 4, and a lower amount of outgas generation.

In addition, referring to Comparative Example 5 of Table 9 above, it can be seen that when an acrylic binder (SR-6100) is used as the binder resin, the resolution and outgas characteristics are significantly lowered compared to Examples 1 to 10 and Comparative Examples 1 to 4.

Both Example 1 of Table 6 above and Comparative Examples 6 and 7 of Table 7 contain the same alkali-soluble resin (Polymer 1-1), and each contain a mutually-different photoinitiator. In Example 1, Compound 5-3 was used as a photoinitiator, and in Comparative Examples 6 and 7, OXE-02 (BASF) and 1-hydroxycyclohexyl phenyl ketone were each used as a photoinitiator.

Comparing the amounts of outgas generated in Example 1 and Comparative Examples 6 and 7 through Tables 8 and 9 above, it can be seen that the amount of outgas generated in Comparative Example 6 using OXE-02 (BASF), in which the temperature at which 5% weight loss occurs is 200° C. or higher, was significantly increased compared to those of Example 1 and Comparative Example 7.

In addition, comparing the minimum pattern sizes on the substrates of Example 1 and Comparative Examples 6 and 7, the minimum pattern size on the substrate of Comparative Example 7, in which 1-Hhydroxycyclohexyl phenyl having a maximum molar absorption coefficient of 2,400 (L/mol·cm) (@330 nm) in the region of 320 nm to 380 nm was used as a photoinitiator was shown to be largest compared to those of Example 1 and Comparative Example 6.

Through the above, it can be seen that when the maximum molar absorption coefficient in the region of 320 nm to 380 nm is less than 5,000 (L/mol·cm), the pattern is not properly formed in the exposure step due to low sensitivity, thus having a problem in that the resolution is deteriorated.

Compound 5-3 of the present disclosure is included in the condition where the maximum molar absorption coefficient in the region of 320 nm to 380 nm is 10,000 (L/mol·cm) or more, and the temperature of the 5% weight loss is 200° C. or below, and the minimum pattern size on the substrate is small and the amount of outgas generated is lower compared to the photoinitiators, which are not included in the above conditions, thus being able to significantly improve resolution.

Both Example 6 of Table 6 above and Comparative Examples 8 and 9 of Table 7 contain the same alkali-soluble resin (Polymer 2-1), and each contain mutually-different photoinitiators. In Example 6, Compound 5-3 was used as a photoinitiator, and in Comparative Examples 8 and 9, OXE-02 (BASF) and 1-hydroxycyclohexyl phenyl ketone were each used as a photoinitiator.

When comparing the minimum pattern sizes and the amounts of outgas generation on the substrates of Example 6 and Comparative Examples 8 and 9 with one another, it can be seen that the same tendency appears as when the minimum pattern sizes and the amounts of outgas generation on the substrates were compared between Example 1 and Comparative Examples 6 and 7 above.

The above description is merely illustrative of the present disclosure, and those skilled in the art to which the present disclosure pertains will be able to make various modifications within a range that does not deviate from the essential characteristics of the present disclosure.

Therefore, the embodiments disclosed in this specification are for explanation purposes rather than limiting the present disclosure, and the spirit and scope of the present disclosure are not limited by these embodiments. The protection scope of the present disclosure should be interpreted by the claims, and all descriptions within the scope equivalent thereto should be construed as being included in the scope of the present disclosure.

[Code Explanation]

| | |
|---|---|
| 1: substrate | 2: TFT |
| 3: TFT layer | 4: first electrode |
| 5: pixel separation unit | 6: organic layer |
| 7: second electrode | 8: sealing layer |
| 9: touch screen panel (TSP) | 10: color unit |
| 11: color separation unit | 12: flattening layer |

1. A photosensitive resin composition comprising an alkali-soluble resin; a reactive unsaturated compound; a photoinitiator in which the maximum molar absorption coefficient in the region of 320 nm to 380 nm is 10,000 (L/mol·cm) or more and a 5% weight loss occurs at 200° C. or below; a colorant; and a solvent.

2. The photosensitive resin composition of claim 1, wherein the alkali-soluble resin comprises a repeating unit represented by the following Formula (1): 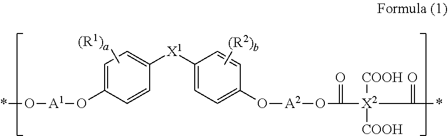
wherein:
1) * represents a part where a bond is connected by a repeating unit,
2) R¹ and R² are each independently selected from the group consisting of hydrogen; deuterium; a halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; and a C₁₋₂₀ alkoxycarbonyl group,
3) R¹ and R² may each form a ring with a neighboring group,
4) a and b are each independently an integer of 0 to 4,
5) X¹ is a single bond, O, CO, SO₂, CR′R″, SiR′R″, Formula (A), or Formula (B),
6) X² is a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; or a combination thereof,
7) R′ and R″ are each independently hydrogen; deuterium; a halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
8) R′ and R″ may each form a ring with a neighboring group,
9) A¹ and A² are each independently Formula (C) or Formula (D),
10) the ratio of Formula (C) to Formula (D) in a polymer chain of the resin including the repeating unit represented by Formula (1) meets 1:9 to 9:1, 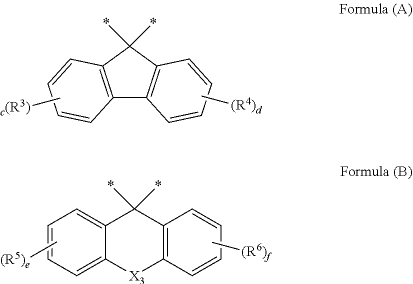
wherein in Formula (A) and Formula (B) above,
11-1) * represents a binding site,
11-2) X₃ is O, S, SO₂, or NR′,
11-3) R′ is hydrogen; deuterium; a halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
11-4) R³ to R⁶ are each independently hydrogen; deuterium; a halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
11-5) R³ to R⁶ are each independently able to form a ring with a neighboring group,
11-6) c to f are each independently an integer of 0 to 4, 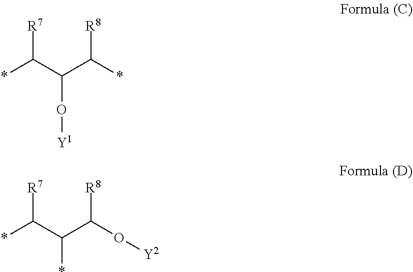
wherein in Formula (C) and Formula (D) above,
12-1) * represents a binding site,
12-2) R⁷ to R¹⁰ are each independently hydrogen; deuterium; a halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
12-3) Y¹ and Y² are each independently Formula (E) or Formula (F), 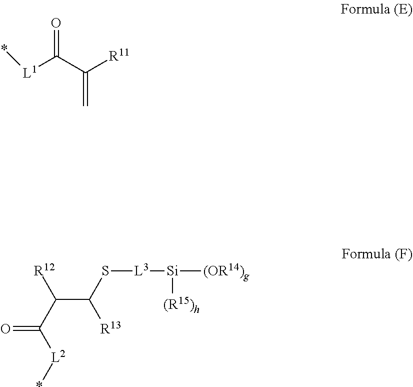
wherein in Formula (E) and Formula (F) above,
13-1) * represents a binding site,
13-2) R¹¹ to R¹⁵ are each independently hydrogen; deuterium; a halogen; a C₆₋₃₀ aryl group; a C₂₋₃₀ heterocyclic group comprising at least one heteroatom among O, N, S, Si, and P;
a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
13-3) L¹ to L³ are each independently a single bond, C₁₋₃₀ alkylene, C₆₋₃₀ arylene, or C₂₋₃₀ heterocyclic ring,
13-4) g and h are each independently an integer from 0 to 3; with the proviso that g+h=3, and
14) the R¹ to R¹⁵, R′, R″, X¹ to X², and L¹ to L³, and the ring formed by a mutual binding between the neighboring groups may each be further substituted with one or more substituents selected from the group consisting of deuterium; a halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group comprising at least one heteroatom among O, N, S, Si, and P; a C₃₋₃₀ alicyclic group; a C₇₋₃₀ arylalkyl group; a C₈₋₃₀ arylalkenyl group; and a combination thereof; or may form a ring between the neighboring substituents.

3. The photosensitive resin composition of claim 1, wherein the weight average molecular weight of the alkali-soluble resin is 1,000 g/mol to 100,000 g/mol.

4. The photosensitive resin composition of claim 1, wherein the ratio of Formula (E) and Formula (F) in the polymer chain of the resin comprising a repeating unit represented by Formula (1) above is 2:0 to 1:1.

5. The photosensitive resin composition of claim 1, wherein the reactive unsaturated compound is included at 1 wt % to 40 wt % based on the total amount of the photosensitive resin composition.

6. The photosensitive resin composition of claim 1, wherein the reactive unsaturated compound comprises a compound represented by the following Formula (2): 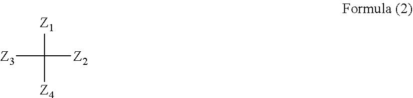
wherein in Formula (2) above,
two or more of Z₁ to Z₄ have the following structure of Formula (G) to be independent of one another; and the remaining Z₁ to Z₄ are each independently hydrogen, deuterium, a halogen, a methyl group, an ethyl group; a methylhydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
* [symbol] L⁴—O [symbol] ₜY₃ Formula (G)
wherein in Formula (G) above,
1) t is an integer of 1 to 20,
2) L⁴ is a single bond, a C₁₋₃₀ alkylene group, C₆₋₃₀ arylene, or C₂₋₃₀ heterocyclic ring,
3) Y₃ is the following Formula (H) or Formula (I), 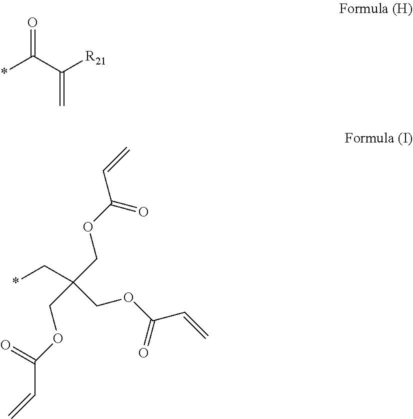
wherein in Formula (H) above,
R₂₁ is hydrogen, deuterium, a halogen, a methyl group, an ethyl group; a methylhydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group.

7. The photosensitive resin composition of claim 1, wherein the colorant is included at 5 wt % to 40 wt % based on the total amount of the photosensitive resin composition.

8. The photosensitive resin composition of claim 1, wherein the colorant comprises at least one of black, red, blue, green, yellow, purple, orange, white, silver, or gold inorganic dyes, organic dyes, inorganic pigments, and organic pigments.

9. The photosensitive resin composition of claim 1, wherein the photoinitiator is included at 0.01 wt % to 10 wt % based on the total amount of the photosensitive resin composition.

10. The photosensitive resin composition of claim 1, wherein the photoinitiator comprises a compound represented by the following Formula (3): 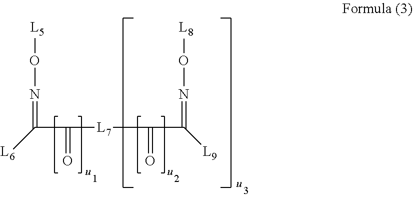
wherein in Formula (3) above,
1) u₁ to u₃ are each independently an integer of 0 or 1,
2) L₅ and L₈ are the following Formula (J),
3) L₆, L₇, and L₉ are each independently a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; a C₁₋₂₀ alkoxycarbonyl group; a C₁₋₃₀ alkylene group; or a C₆₋₃₀ arylene, and 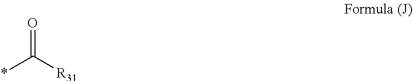
wherein in Formula (J) above,
R₃₁ is hydrogen, deuterium, a halogen, a methyl group, an ethyl group; a methylhydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₃₋₃₀ alicyclic group a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group.

11. The photosensitive resin composition of claim 10, wherein L₆, L₇, and L₉ of Formula (3) above are each independently one of the following Formulas (K) to (N): 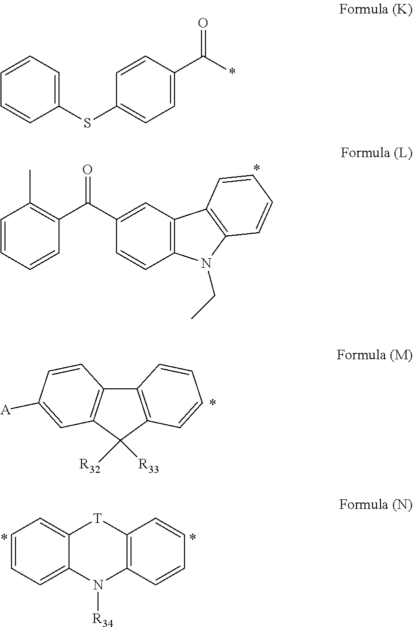
wherein in Formula (M) and Formula (N) above,
1) A is hydrogen; O; S; a silane group; a siloxane group; a boron group; a germanium group; a cyano group; a nitro group; a nitrile group; an amino group substituted or unsubstituted with a C₁₋₃₀ alkyl group, a C₆₋₃₀ aryl group, or a C₂₋₃₀ heterocyclic group; a C₁₋₃₀ alkylthio group; a C₁₋₃₀ alkyl group; a C₁₋₃₀ alkoxy group; a C₆₋₃₀ arylalkoxy group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group comprising at least one heteroatom among O, N, S, Si, and P; a C₃₋₃₀ alicyclic group; a C₇₋₃₀ arylalkyl group; a C₆₋₃₀ arylalkenyl group; and a combination thereof,
2) R₃₂ to R₃₄ are each independently hydrogen; deuterium; a halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group, and
3) T is S, O, or Se.

12. A pattern or film formed from the photosensitive composition according to claim 1.

13. A display device comprising a first electrode formed on a substrate, a second electrode provided to face the first electrode, and the pattern or film formed from the photosensitive composition according to claim 1.

14. The display device of claim 13, wherein the pattern is a color unit or color separation unit.

15. An electronic device comprising the display device of claim 11 and a control unit for driving the display device.
